(19) United States
(12) Patent Application Publication
(10) Pub. No.: US 2026/0088081 A1
(43) Pub. Date: Mar. 26, 2026

(54) SEMICONDUCTOR INTEGRATED CIRCUIT

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Toshiaki DOZAKA, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/319,890

(22) Filed: Sep. 5, 2025

(30) Foreign Application Priority Data
Sep. 24, 2024 (JP) 2024-164833
Mar. 19, 2025 (JP) 2025-045747

(51) Int. Cl. G11C 11/419

(52) U.S. Cl. CPC G11C 11/419

(57) ABSTRACT

According to an embodiment, a semiconductor integrated circuit controls a potential level by charge sharing. The semiconductor integrated circuit performs an operation using a potential level controlled by the charge sharing between a plurality of circuit blocks and a global circuit block. Each of the circuit blocks includes a plurality of memory cells. The potential level is controlled to be a potential level of a read line for reading data provided according to a state of a memory cell.

### CROSS-REFERENCE TO RELATED APPLICATIONS

This application is based upon and claims the benefit of priority from Japanese Patent Application No. 2024-164833, filed on Sep. 24, 2024; and Japanese Patent Application No. 2025-045747, filed on Mar. 19, 2025; the entire contents of all of which are incorporated herein by reference.

### FIELD

Embodiments described herein relate generally to a semiconductor integrated circuit.

### BACKGROUND

In a semiconductor integrated circuit with a conventional general architecture, an operation is performed by a processor such as an MPU, and data is stored in a memory. In recent years, Computing in Memory (CiM; or In-memory computing) has been proposed. According to the CiM, an operation is executed in a semiconductor integrated circuit as a memory and a result of the operation is stored in the memory.

The background of proposing the CiM is as follows. In the operation of the neural network or the machine learning, the product-sum operation is basically performed, and it is recognized that most of the power consumed in the semiconductor integrated circuit that performs such a product-sum operation is not spent on the product-sum operation but is spent on communication between the processor and the memory.

Therefore, by performing the product-sum operation in the CiM, power consumption can be reduced, and an effective processing speed can be improved.

In a case of using an SRAM bit cell as a memory, the SRAM bit cell is configured by a transistor having a relatively small (for example, minimum) size, so that the influence of manufacturing variation may become large, and the variation in the read current may become large. Therefore, it is difficult to perform the product-sum operation by the bit line current by simultaneous reading to configure the CiM.

For suppressing manufacturing variations of transistors, the transistor size is enlarged in some cases. However, the SRAM bit cell is produced in accordance with a specific design rule. Therefore, it is basically impossible to change the size of the SRAM bit cell.

Considering the above-described problems, there is a need to suppress variation in read current in a semiconductor integrated circuit.

### BRIEF DESCRIPTION OF THE DRAWINGS

FIG. 1 is an explanatory diagram of a main part of a memory device to which the embodiment is applied;

FIG. 2 is a signal timing chart in the normal mode;

FIG. 3 is a signal timing chart in the CiM mode in which the product-sum operation is performed on the memory;

FIG. 4 is an explanatory diagram of a calculation result of a bit line level in a case where a product-sum operation is performed in all assumed data states in a case where two-bit CiM with four values is performed in the memory cell of local four banks;

FIG. 5 is an explanatory diagram of a calculation result of a bit line level in a case where a product-sum operation is performed in all assumed data states in a case where three-bit CiM with eight values is performed in memory cells of local eight banks;

FIG. 6 is an explanatory diagram of a configuration principle of a read circuit in any local cell array;

FIG. 7 is an explanatory diagram of a first configuration example of the memory cell array for generating a reference potential (reference voltage) by the charge sharing method;

FIG. 8 is an explanatory diagram of a second configuration example of the memory cell array for generating a reference potential (reference voltage) by the charge sharing method;

FIG. 9 is an explanatory diagram of a third configuration example of the memory cell array for generating a reference potential (reference voltage) by the charge sharing method;

FIG. 10 is an explanatory diagram of a fourth configuration example of the memory cell array for generating a reference potential (reference voltage) by the charge sharing method;

FIG. 11 is an explanatory diagram of a fifth configuration example of the memory cell array for generating a reference potential (reference voltage) by the charge sharing method;

FIG. 12 is an explanatory diagram of a sixth configuration example of the memory cell array for generating a reference potential (reference voltage) by the charge sharing method;

FIG. 13 is an explanatory diagram of a more specific circuit configuration of the memory cell array in the memory device;

FIG. 14A is an operation timing chart (part 1) of the operation side column in the CiM mode of the circuit of FIG. 13;

FIG. 14B is an operation timing chart (part 1) of the generation side column of the reference potential in the CiM mode of the circuit of FIG. 13;

FIG. 15A is an operation timing chart (part 2) of the operation side column in the CiM mode of the circuit of FIG. 13;

FIG. 15B is an operation timing chart (part 2) of the generation side column of the reference potential in the CiM mode of the circuit of FIG. 13;

FIG. 16 is an explanatory diagram of a first connection example of the read circuit in the memory device;

FIG. 17 is an explanatory diagram of the correspondence relationship between the potential levels of the first global bit lines GBLT(0) to GBLT(7), the potential levels of the second global bit lines GBLB(0) to GBLB(7), and the reference voltage in the circuit of FIG. 16;

FIG. 18 is an explanatory diagram of a second connection example of the read circuit in the memory device;

FIG. 19 is a schematic explanatory diagram of a product-sum operation circuit of a digital method;

FIG. 20 is an explanatory diagram of a specific circuit configuration of a data reading part of the memory cell array in the memory device of the second embodiment;

FIG. 21 is an explanatory diagram of a first modification of the second embodiment;

FIG. 22 is an explanatory diagram of a second modification of the second embodiment;

FIG. 23A is an operation timing chart of the operation side column in the CiM mode of the circuit of FIG. 21;

FIG. 23B is an operation timing chart of the generation side column of the reference potential in the CiM mode of the circuit of FIG. 21;

FIG. 24A is an explanatory diagram of a potential difference between the potential of the first global bit line GBLT and the potential of the second global bit line GBLB per local block in a case where the charge collector circuit is not used in the eight-bit CiM;

FIG. 24B is an explanatory diagram of a potential difference between the potential of the first global bit line GBLT and the potential of the second global bit line GBLB per local block in a case where bit line sharing is performed between two columns using a charge collector circuit in the eight-bit CiM;

FIG. 24C is an explanatory diagram of a potential difference between the potential of the first global bit line GBLT and the potential of the second global bit line GBLB per local block in a case where bit line sharing is performed between four columns using a charge collector circuit in eight-bit CiM;

FIG. 25 is an explanatory diagram of a first configuration example of the memory cell array in a case where eight-bit CiM is performed;

FIG. 26 is an explanatory diagram of a second configuration example of the memory cell array in a case where eight-bit CiM is performed;

FIG. 27 is an explanatory diagram of a third configuration example of the memory cell array in a case where eight-bit CiM is performed;

FIG. 28 is an explanatory diagram of a main part of a memory device to which the third embodiment is applied;

FIG. 29 is an operation timing chart of the operation side column in the CiM mode of the circuit of FIG. 28;

FIG. 30 is an explanatory diagram of an exemplary circuit of a conventional latch-type determination circuit;

FIG. 31 is an explanatory diagram of a signal state of each unit of a conventional latch-type determination circuit;

FIG. 32 is an explanatory diagram of an exemplary circuit of the latch-type determination circuit according to the fourth embodiment;

FIG. 33 is a diagram illustrating potential simulation results of the global bit line and the reference bit line;

FIG. 34 is an explanatory diagram of a first aspect of the fifth embodiment; and

FIG. 35 is an explanatory diagram of a second aspect of the fifth embodiment.

### DETAILED DESCRIPTION

According to one embodiment, a semiconductor integrated circuit controls a potential level by charge sharing. The semiconductor integrated circuit is configured to perform an operation using a potential level controlled by the charge sharing between a plurality of circuit blocks and a global circuit block. Each of the circuit blocks includes a plurality of memory cells. The potential level is controlled to be a potential level of a read line for reading data provided according to a state of a memory cell.

Hereinafter, a semiconductor integrated circuit according to embodiments will be described in detail with reference to the accompanying drawings. Note that the present invention is not limited by these embodiments.

First, prior to the description of the embodiment, problems of the present application will be described. While it is possible to generate a reference potential (Ref potential) from a power supply voltage or a band gap voltage, it is assumed that a bit line potential which is an operation result fluctuates in potential (fluctuates due to manufacturing variations) with a parasitic capacitance ratio of a metal layer.

For this reason, in a case where a potential is generated from a power supply voltage or a band gap voltage, trimming or the like for changing a reference potential (Ref potential) according to a variation due to manufacturing variations is essential, and evaluation and trimming in a manufacturing test are required, so that a circuit area is large and a test time (cost) is increased, which is undesirable.

In the present application, the reference potential (Ref potential) is generated using the first global bit line GBLT and the second global bit line GBLB of the adjacent column. By generating the reference potential (Ref potential) by the charge sharing, the influence of manufacturing variation of the bit line capacitance can be offset, and trimming is unnecessary. Therefore, cost reduction can be expected.

### (1) First Embodiment

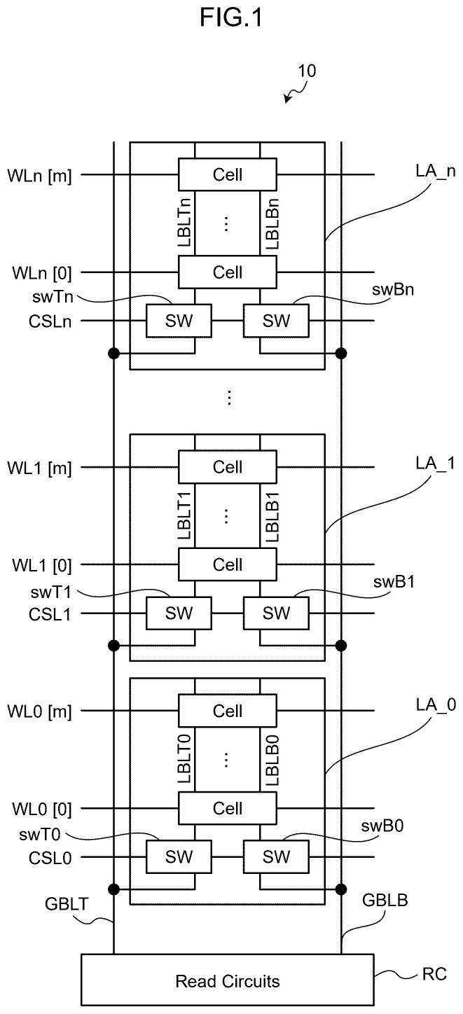

FIG. 1 is an explanatory diagram of a main part of a memory device to which the embodiment is applied. The memory device 10 includes n+1 (n is an integer of 2 or more) local arrays LA_0 to LA_n, the first global bit line GBLT, the second global bit line GBLB, and a read circuit RC. In the above configuration, each of the local arrays LA_0 to LA_n functions as a local circuit block, and the column including the local arrays LA0 to LA_n functions as a global circuit block as a whole (hereinafter, the same applies).

In addition, the first global bit line GBLT and the second global bit line GBLB are configured as a complementary pair of bit lines of the first global bit line GBLT and the second global bit line GBLB (hereinafter, the same applies).

A column selection line CSL(x) and m word lines WLx(0) to WLx(m) are connected to each local array LA_x (x: an integer of 0 to n). Each local array LA_x includes a first local bit line LBLTx, a second local bit line LBLBx, memory cells Cell0 to Celln, a first switch swTx, and a second switch swBx.

In the above configuration, the first local bit line LBLTx and the second local bit line LBLBx are configured as a complementary pair of bit lines (hereinafter, the same applies).

In the above configuration, each memory cell is connected between the first local bit line LBLTx and the second local bit line LBLBx. The first local bit line LBLTx is connected to the read circuit RC via the first switch swTx.

The second local bit line LBLBx is connected to the read circuit RC via the second switch swBx.

The first switch swTx and the second switch swBx are turned on when the corresponding local array LA_x is selected by the column selection line CSL(x). Then, the first switch swTx and the second switch swBx connect the first local bit line LBLTx to the first global bit line GBLT and connect the second local bit line LBLBx to the second global bit line GBLB.

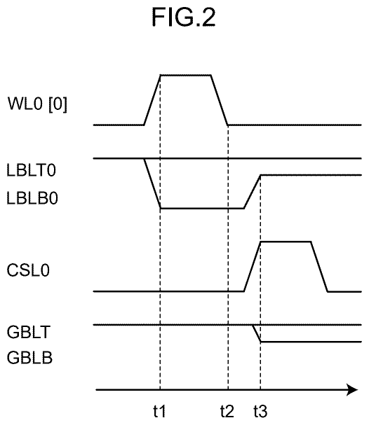

FIG. 2 is a signal timing chart in the normal mode. The example of FIG. 2 is a signal timing chart in a case where data of the memory cell Cell0 constituting the local array LA_0 is read. When the word line WL0(0) is at the “H” (high) level, a first local bit line LBLT0 maintains the “H” level, and a second local bit line LBLB0 transitions to the “L” (low) level.

Subsequently, when the word line WL0(0) transitions to the “L” level and the column selection line CSL(0) transitions to the “H” level, a first switch swT0 and a second switch swB0 are turned on, the memory cell Cell0 is connected to the first global bit line GBLT and the second global bit line GBLB, and the stored data is read by the read circuit RC.

More specifically, any one word line corresponding to the memory cell from which data is to be read is at the “H” level, one of the first local bit line LBLT0 and the second local bit line LBLB0 of the local array LA_0 is at the “H” level, and the other one is at the “L” level (full transition).

Subsequently, when the word line that has been at the “H” level is set to the “L” level and the first switch swT0 and the second switch swB0 are closed by the column selection line CSL(0) corresponding to the word line, the first local bit line LBLT0 is connected to the first global bit line GBLT in the “H” level state, and the second local bit line LBLB0 is connected to the second global bit line GBLB in the “H” level state.

As a result, the charges of the local bit line at the “L” level and the global bit line at the “H” level of the first local bit line LBLT0 or the second local bit line LBLB0 are shared, the potential of the local bit line at the “L” level increases, and the potential of the corresponding global bit line decreases.

The fluctuation amount of the potential at this time is determined by the capacitance value of the local bit line at the “L” level and the capacitance value of the corresponding global bit line. Thus, according to the charge sharing method, since the potential of the bit line is determined by the capacitance value, it is possible to generate the read potential without being affected by the manufacturing variation of the transistor.

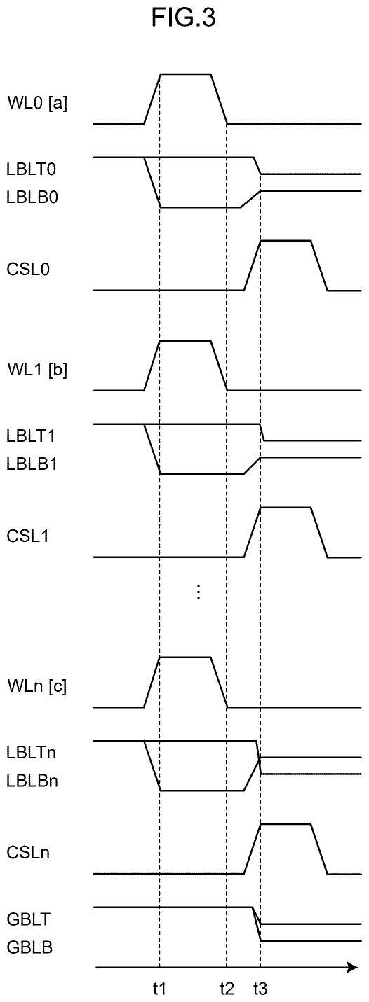

FIG. 3 is a signal timing chart in the CiM mode in which the product-sum operation is performed on the memory.

Any one word line connected to all the local arrays LA_0 to LA_n is at the “H” level, any one of the first local bit line LBLTx and the second local bit line LBLBx of all the local arrays LA_0 to LA_n is at the “H” level, and the other is at the “L” level (full transition). Subsequently, the word line that has been at the “H” level is set to the “L” level, all the column selection lines CSL(0) to CSL(n) are set to the “H” level, and all the first switches swTx and the second switches swBx are closed.

Then, the first local bit line LBLTx of each of the local arrays LA_0 to LA_n is connected to the first global bit line GBLT in the “H” level state, and the second local bit line LBLBx is connected to the second global bit line GBLB in the “H” level state.

As a result, the charges of the local bit line at the “L” level and the global bit line at the “H” level of the first local bit line LBLTx or the second local bit line LBLBx among the local arrays LA_0 to LA_n are shared, the potentials of all the local bit lines at the “L” level increase, and the potentials of all the corresponding global bit lines decrease.

As a result, the potentials of the first global bit line GBLT and the second global bit line GBLB transition to potentials corresponding to the accessed cell data, and the potentials of the first global bit line GBLT and the second global bit line GBLB at this time are a product-sum operation result of the accessed memory cell.

Therefore, this is read by the read circuit RC and subjected to analog/digital conversion, thereby enabling product-sum operation that is not affected by variations in cell current.

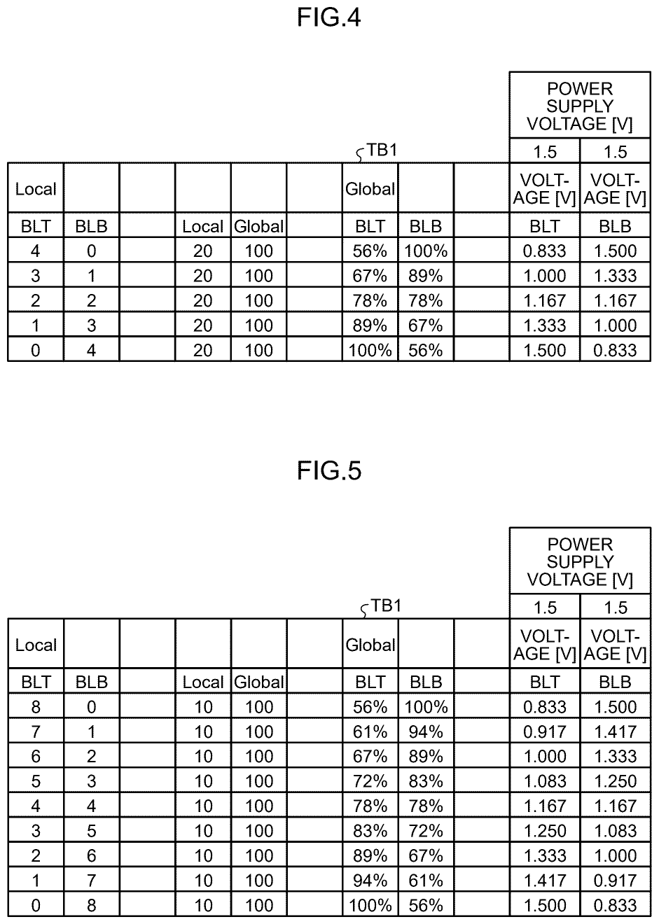

Next, an estimation result of the voltage level of the read bit line in the memory cell array illustrated in FIG. 1 will be described. FIG. 4 is an explanatory diagram of a calculation result of a bit line level in a case where a product-sum operation is performed in all assumed data states in a case where two-bit CiM with four values is performed in the memory cells of local four banks.

In this case, it is assumed that the capacitance ratio between the local bit line and the global bit line is 1:5. As illustrated in the first column from the left in FIG. 4, when the value of a first local bit line LBLT is 4, the value of a second local bit line LBLB is 0.

Similarly, when the values of the first local bit line LBLT are 3, 2, 1, and 0, the values of the second local bit line LBLB are 1, 2, 3, and 4, respectively.

In addition, the potential of the first global bit line GBLT and the potential of the second global bit line GBLB are 56%: 100% when the value of the first local bit line LBLT is 4 as illustrated in the seventh and eighth columns from the left.

Therefore, in a case where the power supply voltages of the first global bit line GBLT and the second global bit line GBLB are 1.5 V, when the value of the first local bit line LBLT is 4, the voltage of the first global bit line GBLT is 0.833 V as illustrated in the second column from the right in FIG. 4, and the voltage of the second global bit line GBLB is 1.500 V as illustrated in the first column from the right in FIG. 4.

Similarly, when the values of the first local bit line LBLT are 3, 2, 1, and 0, the voltages of the first global bit line GBLT are 1.000 V, 1.167 V, 1.333 V, and 1.500 V as illustrated in the second column from the right in FIG. 4.

When the values of the first local bit line LBLT are 3, 2, 1, and 0, the voltages of the second global bit line GBLB are 1.333 V, 1.167 V, 1.000 V, and 0.833 V as illustrated in the first column from the right in FIG. 4.

Therefore, as reference voltages for identifying them, for example, four reference voltages of a first reference voltage Ref1 having a voltage in a range of 1.500 V to 1.333 V for identifying the voltage of the first global bit line GBLT between 1.500 V and 1.333 V, a second reference voltage Ref2 having a voltage in a range of 1.333 V to 1.167 V for identifying the voltage of the first global bit line GBLT between 1.333 V and 1.167 V, a third reference voltage Ref3 having a voltage in a range of 1.167 V to 1.000 V for identifying the voltage of the first global bit line GBLT between 1.167 V and 1.000 V, and a fourth reference voltage Ref4 having a voltage in a range of 1.000 V to 0.833 V for identifying the voltage of the first global bit line GBLT between 1.000 V and 0.833 V are required.

FIG. 5 is an explanatory diagram of a calculation result of a bit line level in a case where a product-sum operation is performed in all assumed data states in a case where three-bit CiM with eight values is performed in memory cells of local eight banks.

In this case, it is assumed that the capacitance ratio between the local bit line and the global bit line is 1:10.

As illustrated in the first column from the left in FIG. 5, when the value of the first local bit line LBLT is 8, the value of the second local bit line LBLB is 0.

Similarly, when the values of the first local bit line LBLT are 7, 6, 5, 4, 3, 2, 1, and 0, the values of the second local bit line LBLB are 1, 2, 3, 4, 5, 6, 7, and 8, respectively.

In addition, the potential of the first global bit line GBLT and the potential of the second global bit line GBLB are 56%: 100% when the value of the first local bit line LBLT is 4 as illustrated in the seventh and eighth columns from the left.

Therefore, in a case where the power supply voltages of the first global bit line GBLT and the second global bit line GBLB are 1.5 V, when the value of the first local bit line LBLT is 8, the voltage of the first global bit line GBLT is 0.833 V as illustrated in the second column from the right in FIG. 5, and the voltage of the second global bit line GBLB is 1.500 V as illustrated in the first column from the right in FIG. 5.

Similarly, when the values of the first local bit line LBLT are 7, 6, 5, 4, 3, 2, 1, and 0, the voltages of the first global bit line GBLT are 0.917 V, 1.000 V, 1.083 V, 1.167 V, 1.250 V, 1.333 V, 1.417 V, and 1.500 V as illustrated in the second column from the right in FIG. 5.

When the values of the first local bit line LBLT are 7, 6, 5, 4, 3, 2, 1, and 0, the voltages of the second global bit line GBLB are 1.417 V, 1.333 V, 1.250 V, 1.167 V, 1.083 V, 1.000 V, 0.917 V, and 0.833 V as illustrated in the first column from the right in FIG. 5.

Therefore, as reference voltages for identifying them, for example, the eight reference voltages are required. The eight reference voltages are a first reference voltage Ref1 having a voltage (for example, an intermediate potential, the same applies hereinafter) within a range of 1.500 V to 1.417 V for identifying the voltage of the first global bit line GBLT between 1.500 V and 1.417 V, a second reference voltage Ref2 having a voltage in the range of 1.417 V to 1.333 V for identifying the voltage of the first global bit line GBLT between 1.417 V and 1.333 V, a third reference voltage Ref3 having a voltage in the range of 1.333 V to 1.250 V for identifying the voltage of the first global bit line GBLT between 1.333 V and 1.250 V, a fourth reference voltage Ref4 having a voltage in the range of 1.250 V to 1.167 V for identifying the voltage of the first global bit line GBLT between 1.250 V and 1.167 V, a fifth reference voltage Ref5 having a voltage in the range of 1.167 V to 1.083 V for identifying the voltage of the first global bit line GBLT between 1.167 V and 1.083 V, a sixth reference voltage Ref6 having a voltage in the range of 1.083 V to 1.000 V for identifying the voltage of the first global bit line GBLT between 1.083 V and 1.000 V, a seventh reference voltage Ref7 having a voltage in the range of 1.000 V to 0.917 V for identifying the voltage of the first global bit line GBLT between 1.000 V and 0.917 V, and an eighth reference voltage Ref8 having a voltage in the range of 0.917 V to 0.833 V for identifying the voltage of the first global bit line GBLT between 0.917 V and 0.833 V.

In any of the case of the example of FIG. 4 and the case of the example of FIG. 5, in order to generate the actual reference voltage, it is only required to set the memory cell to an assumed data state and generate the intermediate potential of the obtained global bit line potential as the reference voltage, but when the number of reference voltages is large, the area of the memory cell for generating the reference voltage increases.

In addition, the potential change of the first global bit line GBLT and the potential change of the second global bit line GBLB have a symmetrical relationship.

Therefore, in the case of the example of FIG. 4, for example, using a first reference voltage Ref1 having a voltage in the range of 1.500 V to 1.333 V for identifying the voltage of the first global bit line GBLT between 1.500 V and 1.333 V and a second reference voltage Ref2 having a voltage in the range of 1.333 V to 1.167 V for identifying the voltage of the first global bit line GBLT between 1.333 V and 1.167 V, by comparing the first reference voltage Ref1 or the second reference voltage Ref2 with the voltage of the second global bit line when the value of the first local bit line LBLT is 4 to 2, and comparing the first reference voltage Ref1 or the second reference voltage Ref2 with the voltage of the first global bit line GBLT when the value of the first local bit line LBLT is 2 to 0, two types of reference voltages may be provided. Therefore, the area of the memory cell for generating the reference voltage can be halved.

In the above description, the case of using the first reference voltage Ref1 or the second reference voltage Ref2 is described. However, using the third reference voltage Ref3 and the fourth reference voltage Ref4, by comparing the third reference voltage Ref3 or the fourth reference voltage Ref4 with the voltage of the first global bit line GBLT when the value of the first local bit line LBLT is 4 to 2, and comparing the third reference voltage Ref3 or the fourth reference voltage Ref4 with the voltage of the second global bit line GBLB when the value of the first local bit line LBLT is 2 to 0, two types of reference voltages may be provided in this case as well. Therefore, the area of the memory cell for generating the reference voltage can be halved.

Similarly, in the case of the example of FIG. 5, for example, using a first reference voltage Ref1 having a voltage in the range of 1.500 V to 1.417 V for identifying the voltage of the first global bit line GBLT between 1.500 V and 1.417 V, a second reference voltage Ref2 having a voltage in the range of 1.417 V to 1.333 V for identifying the voltage of the first global bit line GBLT between 1.417 V and 1.333 V, a third reference voltage Ref3 having a voltage in the range of 1.333 V to 1.250 V for identifying the voltage of the first global bit line GBLT between 1.333 V and 1.250 V, and a fourth reference voltage Ref4 having a voltage in the range of 1.250 V to 1.167 V for identifying the voltage of the first global bit line GBLT between 1.250 V and 1.167 V, by comparing the first reference voltage Ref1 to the fourth reference voltage Ref4 with the voltage of the second global bit line GBLB when the value of the first local bit line LBLT is 8 to 4, and comparing the first reference voltage Ref1 to the fourth reference voltage Ref4 with the voltage of the first global bit line GBLT when the value of the first local bit line LBLT is 4 to 0, four types of reference voltages may be provided. Therefore, the area of the memory cell for generating the reference voltage can be halved.

In the above description, the case of using the first reference voltage Ref1 to the fourth reference voltage Ref4 is described. Using the fifth reference voltage Ref5 to the eighth reference voltage Ref8, by comparing the fifth reference voltage Ref5 to the eighth reference voltage Ref8 with the voltage of the first global bit line when the value of the first local bit line LBLT is 8 to 4, and comparing the fifth reference voltage Ref5 to the eighth reference voltage Ref8 with the voltage of the second global bit line when the value of the first local bit line LBLT is 4 to 0, four types of reference voltages may be provided in this case as well. Therefore, the area of the memory cell for generating the reference voltage can be halved.

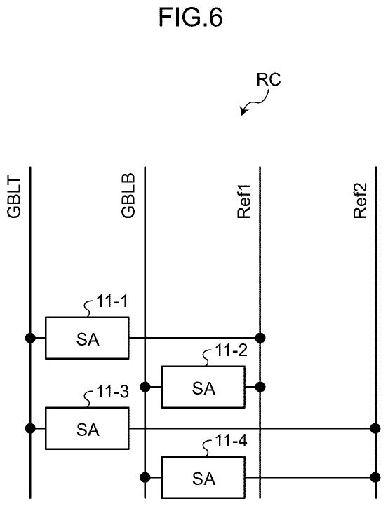

FIG. 6 is an explanatory diagram of a configuration principle of a read circuit in any local cell array. In FIG. 6, a configuration example of the read circuit RC is illustrated, which is applied in a case where the first reference voltage Ref1 and the second reference voltage Ref2 are used as reference voltages in a case where two-bit CiM with four values is performed in the memory cell of the local four banks.

The read circuit RC includes a first sense amplifier (SA) 11-1 having one input terminal connected to the first global bit line GBLT corresponding to a local cell array from which data is to be read and the other input terminal connected to the first reference voltage Ref1 generated by charge sharing using the first global bit line GBLT and the second global bit line GBLB in an adjacent column of the local cell array generating the first reference voltage Ref1, a second sense amplifier 11-2 having one input terminal connected to the first global bit line GBLT corresponding to the local cell array from which data is to be read and the other input terminal connected to the second reference voltage Ref2 generated by charge sharing using the first global bit line GBLT and the second global bit line GBLB in an adjacent column of the local cell array generating the second reference voltage Ref2, a third sense amplifier 11-3 having one input terminal connected to the second global bit line GBLB corresponding to a local cell array from which data is to be read and the other input terminal connected to a first reference voltage Ref1, and a fourth sense amplifier 11-4 having one input terminal connected to the second global bit line GBLB corresponding to a local cell array from which data is to be read and the other input terminal connected to the second reference voltage Ref2.

In this case, as the first sense amplifier 11-1 to the fourth sense amplifier 11-4, sense amplifiers used for conventional SRAM reading with a track record are used.

Then, the read circuit RC outputs a product-sum operation result obtained by performing a digital process on the read results from the first sense amplifier 11-1 to the fourth sense amplifier 11-4. According to the present embodiment, since the reference voltage serving as the reference potential is generated on the same semiconductor integrated circuit by the charge sharing method as described above, the influence of manufacturing variation of the bit line capacitance can be offset, and trimming is unnecessary. Therefore, cost reduction can be achieved.

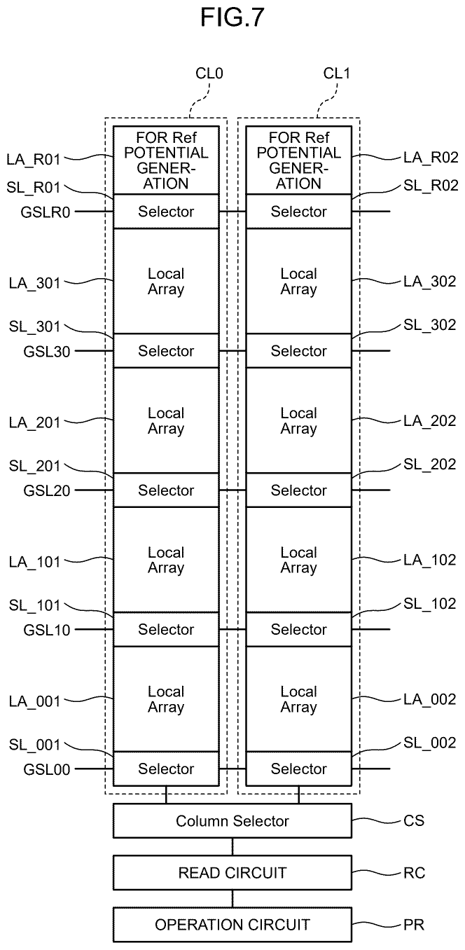

Next, a more specific description will be given. FIG. 7 is an explanatory diagram of a first configuration example of the memory cell array for generating a reference potential (reference voltage) by the charge sharing method. In the example of FIG. 7, two columns CL0 and CL1 are provided, and when the product-sum operation on one column is performed, the reference potential is generated using the local array for generating the reference potential of the other column, and the product-sum operation is performed.

The column CL0 includes the first global bit line GBLT (not illustrated) and the second global bit line GBLB (not illustrated), four local arrays LA_001 to LA_301 connected thereto, and further includes a local array LA_R01 for generating the reference potential connected to the first global bit line GBLT (not illustrated) and the second global bit line GBLB (not illustrated).

The column CL1 includes the first global bit line GBLT (not illustrated) and the second global bit line GBLB (not illustrated), four local arrays LA_002 to LA_302 connected thereto, and further includes a local array LA_R02 for generating the reference potential connected to the first global bit line GBLT (not illustrated) and the second global bit line GBLB (not illustrated).

In the above configuration, the local array LA_R01 generates a reference voltage to be a reference potential when accessing the column CL1. The local array LA_R01 is constituted by half the number of rows (the number of rows: the number of word lines) of the other local arrays LA_001 to LA_301.

Similarly, the local array LA_R02 generates a reference voltage to be a reference potential when accessing the column CL0. The local array LA_R02 is constituted by half the number of rows (the number of rows: the number of word lines) of the other local arrays LA_002 to LA_302.

The reason is that an intermediate potential such as an intermediate potential between 0 and 1 and an intermediate potential between 1 and 2 is generated. The potential Vbl of the bit line is expressed by the following expression when the capacitance of the local bit line is CLBL, the capacitance of the global bit line is CGBL, and the power supply voltage is VPW.

$$Vb 1 = ( 1 - ( CLBL / CGBL + CLBL ) ) \times VPW$$

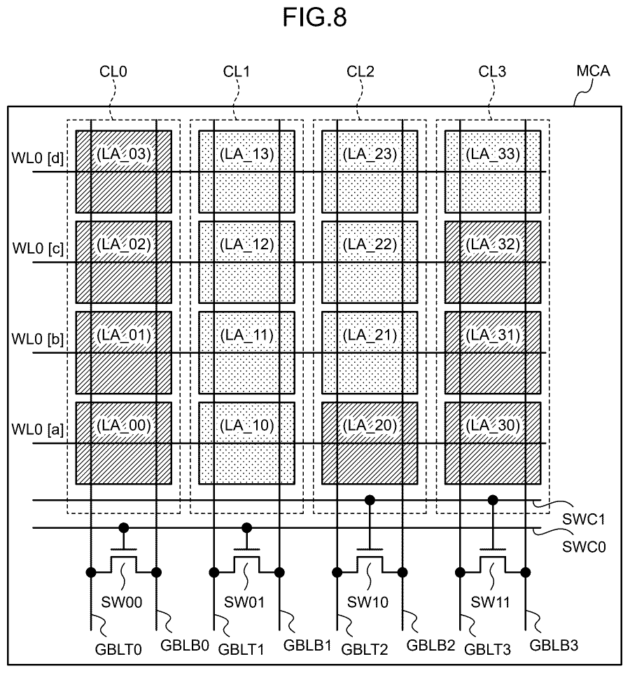

FIG. 8 is an explanatory diagram of a second configuration example of the memory cell array for generating a reference potential (reference voltage) by the charge sharing method.

In the example of FIG. 8, the memory cell array MCA includes four columns CL0, CL1, CL2, and CL3, and in a case where the product-sum operation on the columns CL0 and CL1 is performed, the reference potential for the product-sum operation is generated using at least some of the local arrays LA_20 to LA_23 and LA_30 to LA_33 constituting the columns CL2 and CL3.

When the product-sum operation on the columns CL2 and CL3 is performed, the reference potential for performing the product-sum operation is generated using at least some of the local arrays LA_00 to LA_03 and LA_10 to LA_13 constituting the columns CL0 and CL1.

The column CL0 includes the first global bit line GBLT and the second global bit line GBLB. Further, a switch SW00 for short-circuiting the first global bit line GBLT and the second global bit line GBLB is provided, and the switch SW00 is controlled via a switch control line SWC0.

The column CL1 includes the first global bit line GBLT and the second global bit line GBLB. Further, a switch SW01 for short-circuiting the first global bit line GBLT and the second global bit line GBLB is provided, and the switch SW01 is controlled via the switch control line SWC0.

The column CL2 includes the first global bit line GBLT and the second global bit line GBLB. Further, a switch SW10 for short-circuiting the first global bit line GBLT and the second global bit line GBLB is provided, and the switch SW10 is controlled via a switch control line SWC1.

The column CL3 includes the first global bit line GBLT and the second global bit line GBLB. Further, a switch SW11 for short-circuiting the first global bit line GBLT and the second global bit line GBLB is provided, and the switch SW11 is controlled via the switch control line SWC1.

In FIG. 8, the product-sum operation is to be performed on the column CL0. Therefore, the local arrays LA_00 to LA_03 constituting the column CL0 are hatched with fine right upward oblique lines in FIG. 8 to indicate that the first local bit line LBLT of the local arrays is connected to the first global bit line GBLT and the second local bit line LBLB is connected to the second global bit line GBLB (the same applies hereinafter).

On the other hand, the column CL1 on which the product-sum operation is not to be performed is sandy soil-like hatched to indicate that the first local bit line LBLT of the local arrays LA10 to LA13 is not connected to the first global bit line GBLT and the second local bit line LBLB is not connected to the second global bit line GBLB (the same applies hereinafter).

Note that, in the columns (in the example of FIG. 8, the column CL2 and the column CL3) for generating the reference potential, there are local arrays LA21 to LA23 and LA33 sandy soil-like hatched, and in these local arrays, since the first local bit line LBLT is not connected to the first global bit line GBLT and the second local bit line LBLB is not connected to the second global bit line GBLB, the load capacitance is different from that of the column on which the product-sum operation is performed, and thus the reference potential includes an error.

Therefore, in order to reduce this error, only the bit line at the “H” level may be connected in the local array filled in a light color.

In addition, in the column for generating the reference potential, an intermediate value such as 0.5 or 1.5 cannot be output in a non-short-circuit state of the first global bit lines GBLT0/GBLT1/GBLT2/GBLT3 and the second global bit lines GBLB0/GBLB1/GBLB2/GBLB3 as the corresponding complementary pair. Therefore, in the case of the example of FIG. 8, by turning on the switch SW10 to short-circuit the first global bit line GBLT2 and the second global bit line GBLB2, the capacitance of the global bit line is doubled, and an intermediate value can be output.

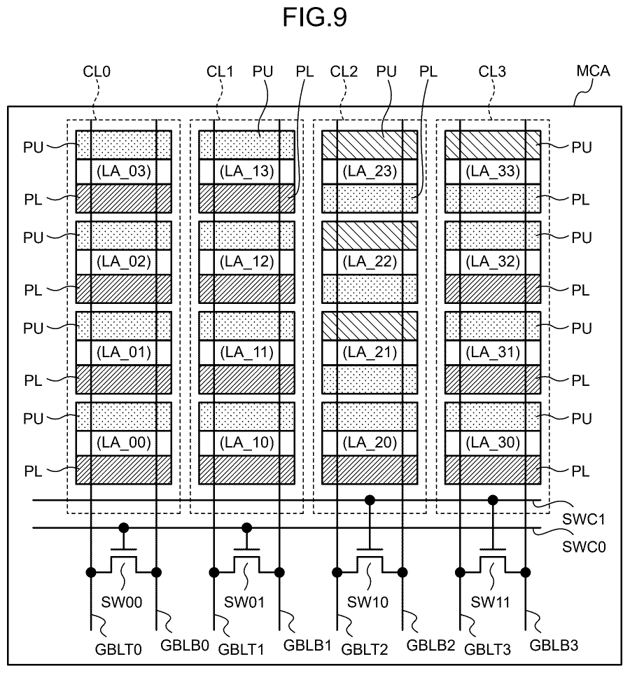

FIG. 9 is an explanatory diagram of a third configuration example of the memory cell array for generating a reference potential (reference voltage) by the charge sharing method. In the example of FIG. 9, as in the case of FIG. 8, the memory cell array MCA includes four columns CL0, CL1, CL2, and CL3, and when the product-sum operation on the columns CL0 and CL1 is performed, the reference potential for the product-sum operation is generated using at least some of the local arrays LA_20 to LA_23 and LA_30 to LA_33 constituting the columns CL2 and CL3. When the product-sum operation on the columns CL2 and CL3 is performed, the reference potential for performing the product-sum operation is generated using at least some of the local arrays LA_00 to LA_03 and LA_10 to LA_13 constituting the columns CL0 and CL1.

The third configuration example of FIG. 9 is different from the configuration example of FIG. 8 in that each of the local arrays LA_00 to LA_03 constituting the column CL0, the local arrays LA_10 to LA_13 constituting the column CL1, the local arrays LA_20 to LA_23 constituting the column CL2, and the local arrays LA_30 to LA_33 constituting the column CL3 is divided into two of an array region PU and an array region PL to have different functions.

More specifically, in FIG. 9, for example, an array region (this region is a region where the first local bit line LBLT of the local array is connected to the first global bit line GBLT and the second local bit line LBLB is connected to the second global bit line GBLB) that is hatched with fine right upward oblique lines, an array region (this region is a region in which the first local bit line LBLT of the local array is not connected to the first global bit line GBLT and the second local bit line LBLB is not connected to the second global bit line GBLB) that is sandy soil-like hatched, and an array region (this region is a region in which the first local bit line LBLT at the “H” level state is connected to the first global bit line GBLT and the second local bit line LBLB at the “H” level is connected to the first global bit line GBLT at the “H” level state to perform the charge sharing operation) that is hatched with fine left upward oblique lines are formed.

Also by adopting such a configuration, it is possible to connect the local bit line pair at the “H” level and the global bit line pair, and the error of the reference potential is reduced as compared with the configuration example of FIG. 8.

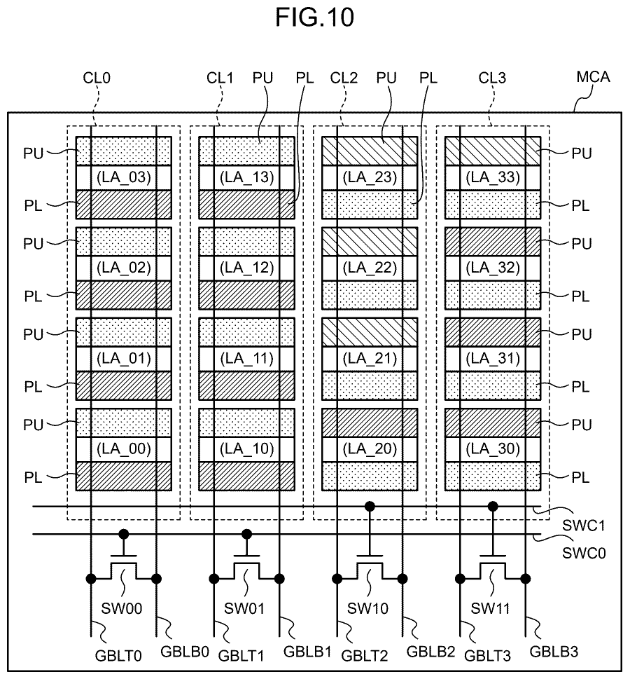

FIG. 10 is an explanatory diagram of a fourth configuration example of the memory cell array for generating a reference potential (reference voltage) by the charge sharing method. In the example of FIG. 10, as in the case of FIG. 9, the memory cell array MCA includes four columns CL0, CL1, CL2, and CL3, and when the product-sum operation on the columns CL0 and CL1 is performed, the reference potential for the product-sum operation is generated using at least some of the local arrays LA_20 to LA_23 and LA_30 to LA_33 constituting the columns CL2 and CL3.

When the product-sum operation on the columns CL2 and CL3 is performed, the reference potential for performing the product-sum operation is generated using at least some of the local arrays LA_00 to LA_03 and LA_10 to LA_13 constituting the columns CL0 and CL1.

The fourth configuration example of FIG. 10 is different from the third configuration example of FIG. 9 in that an array region (this region is a region in which the first local bit line LBLT of the local array is not connected to the first global bit line GBLT and the second local bit line LBLB is not connected to the second global bit line GBLB) that is sandy soil-like hatched is disposed close to the array region PU on the column CL0 side and the column CL1 side, and is disposed close to the array region PL on the column CL2 side and the column CL3 side when each of the local arrays LA_00 to LA_03 constituting the column CL0, the local arrays LA_10 to LA_13 constituting the column CL1, the local arrays LA_20 to LA_23 constituting the column CL2, and the local arrays LA_30 to LA_33 constituting the column CL3 is divided into two of the array region PU and the array region PL to have the different function.

However, even by adopting such a configuration, it is possible to connect the local bit line pair and the global bit line pair at the “H” level, and the reference potential error is reduced as compared with the configuration example of FIG. 8.

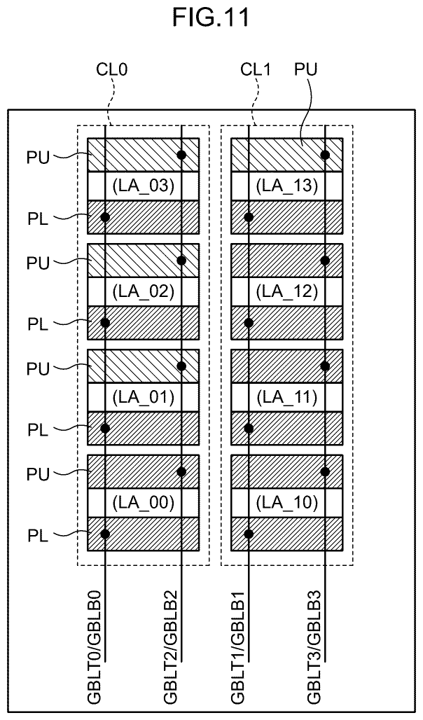

FIG. 11 is an explanatory diagram of a fifth configuration example of the memory cell array for generating a reference potential (reference voltage) by the charge sharing method. Note that, in FIG. 11, the switch SW10 or the switch SW11 and its related configuration are not illustrated.

In the fifth configuration example of FIG. 11, as in the configuration examples of FIGS. 9 and 10, when each of the local arrays LA_00 to LA_03 constituting the column CL0, the local arrays LA_10 to LA_13 constituting the column CL1, the local arrays LA_20 to LA_23 constituting the column CL2, and the local arrays LA_30 to LA_33 constituting the column CL3 is divided into two of the array region PU and the array region PL to have different functions, in the array region PU and the array region PL of the same local array, one is caused to perform the CiM operation and the other is caused to perform the operation for generating the reference potential.

Note that, in FIG. 11, for easy understanding, a pair of global bit lines is represented by one global bit line, and description thereof is omitted. According to this configuration, all the local arrays play various roles, and unnecessary arrays or columns can be eliminated. As a result, the configuration can be made with a small area.

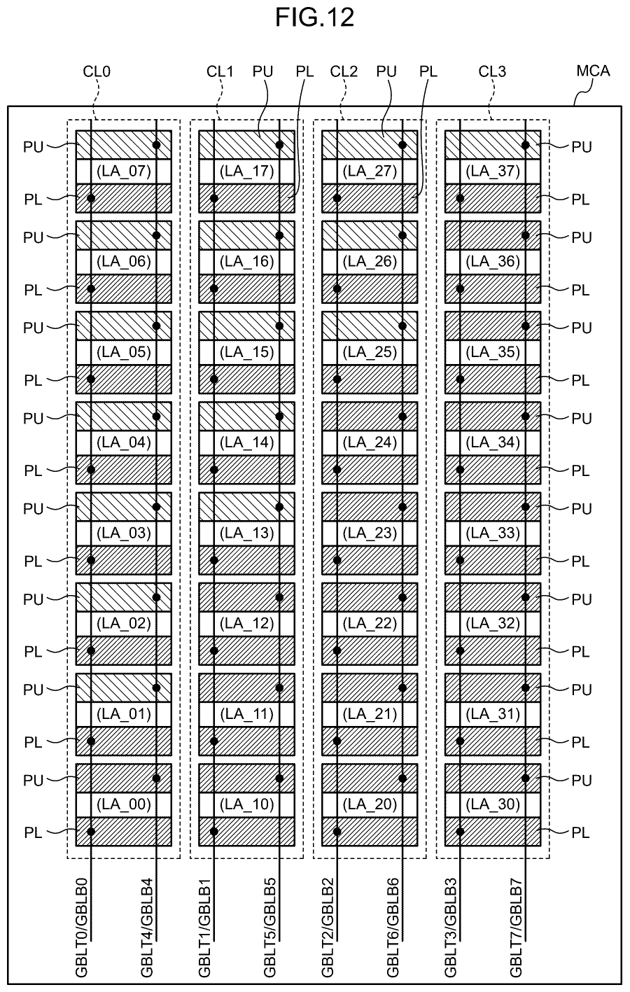

FIG. 12 is an explanatory diagram of a sixth configuration example of the memory cell array for generating a reference potential (reference voltage) by the charge sharing method. FIG. 12 illustrates the CiM configuration with eight values while FIG. 11 illustrates the CiM configuration example with four values.

Also in the sixth configuration example of FIG. 12, for easy understanding, a pair of global bit lines is represented by one global bit line, and description thereof is omitted.

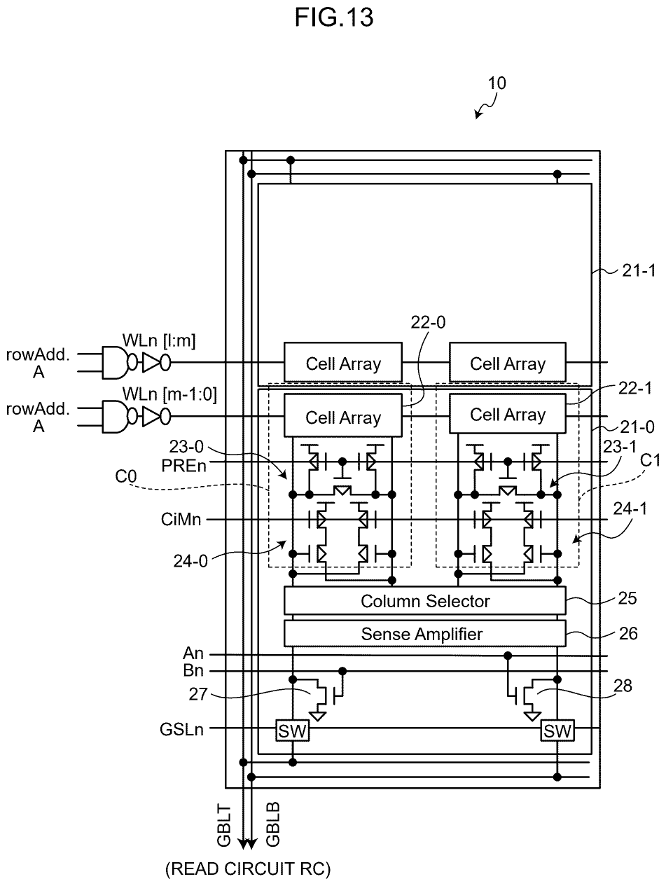

FIG. 13 is an explanatory diagram of a more specific circuit configuration of the memory cell array in the memory device. In FIG. 13, cell array blocks 21-0 and 21-1 corresponding to two columns are illustrated.

In this case, since the cell array block 21-0 and the cell array block 21-1 have the same configuration, the cell array block 21-0 will be described as an example. The cell array block 21-0 includes cell arrays 22-0 and 22-1, precharge auxiliary circuits 23-0 and 23-1, operation mode switching circuits 24-0 and 24-1, a column selector 25, a sense amplifier 26, a reference potential generation data setting circuit 27, and a data reset circuit 28.

In the cell arrays 22-0 and 22-1, the memory cell selected by a word line selected by a word selection signal from a corresponding word selector (not illustrated) is connected to the first local bit line LBLT and the second local bit line LBLB.

In a state where the first local bit line LBLT and the second local bit line LBLB are short-circuited at the time of precharge, the precharge auxiliary circuit discharges the charge corresponding to the fluctuation in the bit line potential.

The operation mode switching circuits 24-0 and 24-1 set the operation mode to either a normal mode in which the selected column is read/written from and to the memory cell as usual or a CiM mode in which the product-sum operation is performed based on the data of the memory cells.

As a result, in the normal mode, the target memory cell is connected to the first global bit line GBLT and the second global bit line GBLB via the first local bit line LBLT and the second local bit line LBLB, and the read processing or the write processing is performed.

In addition, in the CiM mode, the product-sum operation is performed on data of plural target memory cells, and a product-sum operation result is output to the read circuit RC via the first global bit line GBLT and the second global bit line GBLB. The column selector 25 selects a column from which data is to be read or a column on which the product-sum operation is to be performed from the column C0 or the column C1 and connects the selected column to the sense amplifier.

The sense amplifier 26 amplifies a signal level of data read from the memory cell of the cell array connected via the column selector 25 to output the data to the read circuit RC. When there is no problem with the low-speed operation, it is not necessary to provide the sense amplifier 26. The reference potential generation data setting circuit 27 sets data for generating a reference potential in the memory cell array.

The data reset circuit 28 sets the potential level of the local bit line to the same setting as in the case of reading the “0” data without opening the word line, and performs charge sharing with the global bit line.

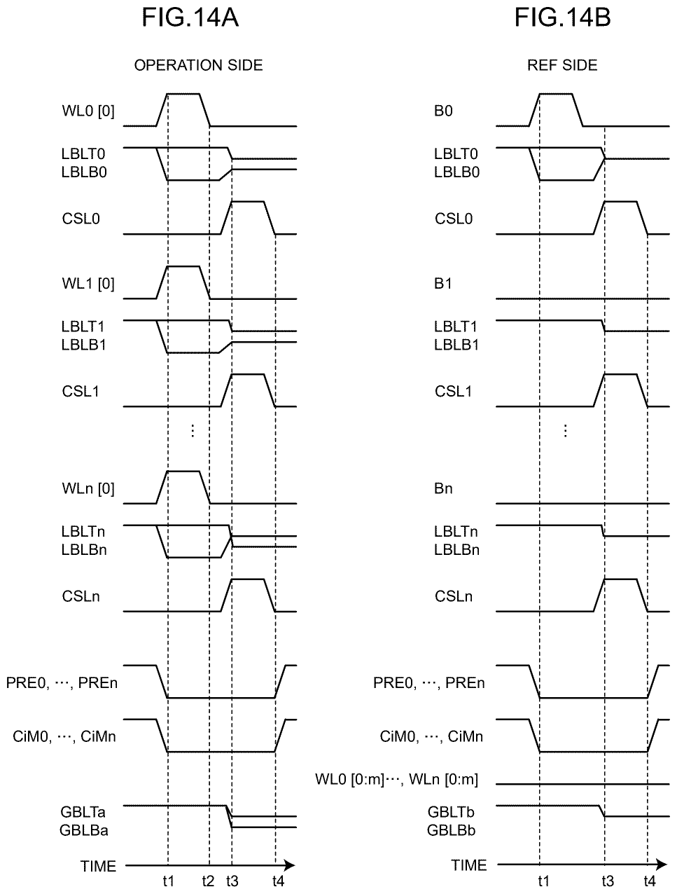

Next, a specific operation will be described. FIG. 14A is an operation timing chart (part 1) of the operation side column in the CiM mode of the circuit of FIG. 13.

FIG. 14B is an operation timing chart (part 1) of the generation side column of the reference potential in the CiM mode of the circuit of FIG. 13.

In the operation side column in the CiM mode, as illustrated in FIG. 14A, at time t1, the word line corresponding to the memory cell that actually performs the operation transitions to the “H” level, and transitions to the potential corresponding to the data held by the memory cell corresponding to the word line.

In addition, the precharge enable lines PRE0 to PREn transition to the “L” level, and the precharge ends.

Further, the operation mode switching lines CiM0 to CiMn transition to the “L” level, and the operation mode transitions to the CiM mode. The transition may be made at time t2.

On the other hand, in the reference potential generation side column, as illustrated in FIG. 14B, at time t1, the data setting lines B0 to Bn corresponding to the memory cell for actually generating the reference potential transition to the “H” level, and the corresponding memory cells transition to the “L” level.

In addition, the precharge enable lines PRE0 to PREn transition to the “L” level, and the precharge ends.

Further, the operation mode switching lines CiM0 to CiMn transition to the “L” level, and the operation mode transitions to a reference potential supply mode corresponding to the CiM mode. The transition may be made at time t2.

Thereafter, at time t2, the word line transitions to the “L” level.

When the column select lines CSL1 to CSLn transition to the “H” level at time t3, in the operation side column, the first local bit line LBLT and the second local bit line LBLB corresponding to the memory cell that actually performs the operation transition to a predetermined level corresponding to the operation result.

As a result, each of the first global bit line GBLT and the second global bit line GBLB of the operation side column transitions to a level corresponding to the operation result of the operation side column, and the operation result is output.

On the other hand, in the reference potential generation side column, the first local bit line LBLT and the second local bit line LBLB corresponding to the memory cell that generates the reference potential enter the charge sharing state, transition to the same predetermined level corresponding to the value of the reference potential, and output of the reference potential is performed.

Thereafter, when the column select lines CSL1 to CSLn transition to the “L” level at time t4, in the operation side column, the precharge enable lines PRE0 to PREn transition to the “H” level and start precharging.

The operation mode switching lines CiM0 to CiMn transition to the “H” level, the operation mode transitions to the normal mode, and the process ends.

On the other hand, in the reference potential generation side column, the precharge enable lines PRE0 to PREn transition to the “H” level and start the precharge.

The operation mode switching lines CiM0 to CiMn transition to the “H” level, the operation mode transitions to the normal mode, and the process ends. As described above, the memory device can generate the reference potential with high reliability in the semiconductor integrated circuit including the SRAM bit cell, and can perform the product-sum operation with high reliability on the semiconductor integrated circuit.

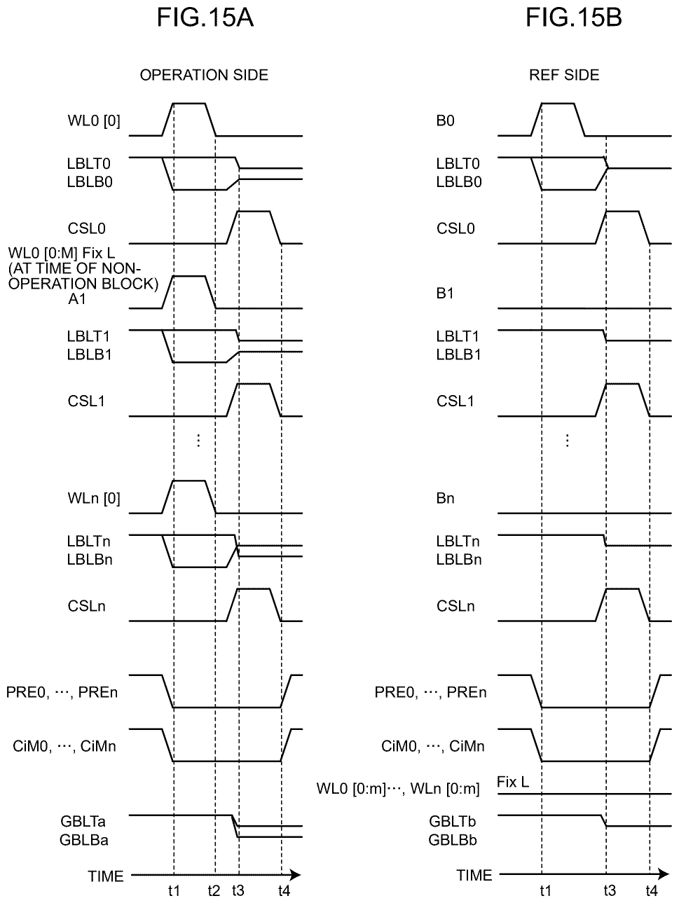

FIG. 15A is an operation timing chart (part 2) of the operation side column in the CiM mode of the circuit of FIG. 13.

FIG. 15B is an operation timing chart (part 2) of the generation side column of the reference potential in the CiM mode of the circuit of FIG. 13.

FIGS. 15A and 15B are different from FIGS. 14A and 14B in that the word line is fixed at the “L” level in the non-operation block in the operation side column, and instead, a data reset line A is at the “H” level at time t1, and the data of the corresponding memory cell is set to “0”. Other operations are the same as those in FIGS. 14A and 14B.

Therefore, in the examples of FIGS. 15A and 15B, the memory device can generate the reference potential with high reliability in the semiconductor integrated circuit including the SRAM bit cell, and can perform the product-sum operation with high reliability on the semiconductor integrated circuit.

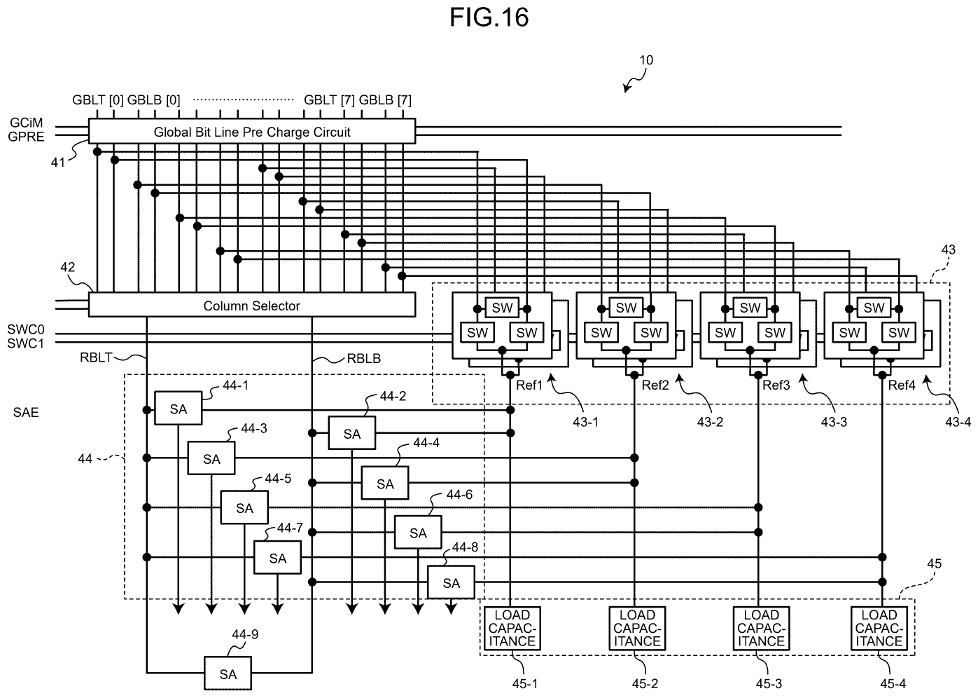

FIG. 16 is an explanatory diagram of a first connection example of the read circuit in the memory device. In FIG. 16, eight columns (first column to eighth column) (not illustrated) are connected to a global bit line precharge circuit 41.

The memory device 10 includes the global bit line precharge circuit 41, a column selector 42, a reference voltage generation circuit unit 43, a sense amplifier unit 44, and a load capacitance adjustment unit 45.

The global bit line precharge circuit 41 precharges the first global bit lines GBLT(0) to GBLT(7) and the second global bit lines GBLB(0) to GBLB(7) corresponding to eight bits to a predetermined potential.

The column selector 42 selects a column including a memory cell from which data is to be read from among the eight columns and connects the column to an output line.

The reference voltage generation circuit unit 43 includes a first reference voltage generation circuit 43-1 that performs a charge sharing operation with a voltage corresponding to data of a memory cell corresponding to a first column corresponding to the first global bit line GBLT(0) and the second global bit line LBLB(0) and a voltage corresponding to data of a memory cell corresponding to a fifth column corresponding to the first global bit line GBLT(4) and the second global bit line LBLB(4) to output the first reference voltage Ref1 as a reference potential.

In addition, the reference voltage generation circuit unit 43 includes a second reference voltage generation circuit 43-2 that performs a charge sharing operation with voltages corresponding to a second column corresponding to the first global bit line GBLT(1) and the second global bit line LBLB(1) and voltages corresponding to a sixth column corresponding to the first global bit line GBLT(5) and the second global bit line LBLB(5) to output the second reference voltage Ref2 as a reference potential.

In addition, the reference voltage generation circuit unit 43 includes a third reference voltage generation circuit 43-3 that performs a charge sharing operation with a voltage corresponding to data of a memory cell of a third column corresponding to the first global bit line GBLT(2) and the second global bit line LBLB(2) and a voltage corresponding to a seventh column corresponding to the first global bit line GBLT(6) and the second global bit line LBLB(6) to output the third reference voltage Ref3 as a reference potential.

In addition, the reference voltage generation circuit unit 43 includes a fourth reference voltage generation circuit 43-4 that performs a charge sharing operation with voltages corresponding to a fourth column corresponding to the first global bit line GBLT(3) and the second global bit line LBLB(3) and voltages corresponding to an eighth column corresponding to the first global bit line GBLT(7) and the second global bit line LBLB(7) to output the fourth reference voltage Ref4 as a reference potential.

The sense amplifier unit 44 includes a first sense amplifier 44-1 having one end connected to a first output line LO1 of the column selector 42 and the other end connected to the first reference voltage generation circuit 43-1, and a second sense amplifier 44-2 having one end connected to a second output line LO2 of the column selector 42 and the other end connected to the first reference voltage generation circuit 43-1.

In addition, the sense amplifier unit 44 includes a third sense amplifier 44-3 having one end connected to the first output line LO1 of the column selector 42 and the other end connected to the second reference voltage generation circuit 43-2, and a fourth sense amplifier 44-4 having one end connected to the second output line LO2 of the column selector 42 and the other end connected to the second reference voltage generation circuit 43-2.

In addition, the sense amplifier unit 44 includes a fifth sense amplifier 44-5 having one end connected to the first output line LO1 of the column selector 42 and the other end connected to the third reference voltage generation circuit 43-3, and a sixth sense amplifier 44-6 having one end connected to the second output line LO2 of the column selector 42 and the other end connected to the third reference voltage generation circuit.

In addition, the sense amplifier unit 44 includes a seventh sense amplifier 44-7 having one end connected to the first output line LO1 of the column selector 42 and the other end connected to the fourth reference voltage generation circuit 43-4, and an eighth sense amplifier 44-8 having one end connected to the second output line LO2 of the column selector 42 and the other end connected to the fourth reference voltage generation circuit.

Moreover, the sense amplifier unit 44 includes a ninth sense amplifier having one end connected to the first output line LO1 of the column selector 42 and the other end connected to the second output line LO2 of the column selector 42 as necessary, and operating in the normal operation mode.

The load capacitance adjustment unit 45 includes a first load capacitance adjustment circuit 45-1 to a fourth load capacitance adjustment circuit 45-4 in order to adjust a difference in parasitic load between the first global bit line GBLT and the second global bit line GBLB. In this case, the first load capacitance adjustment circuit 45-1 is connected to the output terminal of the first reference voltage generation circuit 43-1, the second load capacitance adjustment circuit 45-2 is connected to the output terminal of the second reference voltage generation circuit 43-2, the third load capacitance adjustment circuit 45-3 is connected to the output terminal of the third reference voltage generation circuit 43-3, and the fourth load capacitance adjustment circuit 45-4 is connected to the output terminal of the fourth reference voltage generation circuit 43-4.

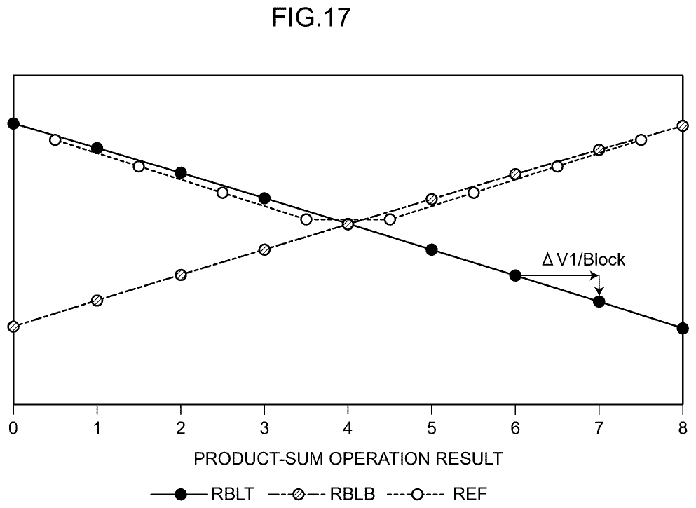

FIG. 17 is an explanatory diagram of the correspondence relationship between the potential levels of the first global bit lines GBLT(0) to GBLT(7), the potential levels of the second global bit lines GBLB(0) to GBLT(7), and the reference voltage in the circuit of FIG. 16.

As illustrated in FIG. 17, the gradient of the reference voltage is substantially equal to the gradient of the potential level of the first global bit lines GBLT(0) to GBLT(7) and the gradient of the potential level of the second global bit lines GBLB(0) to GBLT(7). Therefore, according to the connection state of the read circuit having the above configuration, when the reference voltage (in the case of the above example, the first reference voltage to the fourth reference voltage) used for data reading is generated by removing the influence of manufacturing variation of the semiconductor integrated circuit by the charge sharing operation, the influence of the difference in parasitic load between the first global bit line GBLT and the second global bit line GBLB can be reduced. Therefore, data reading can be performed more accurately and reliably.

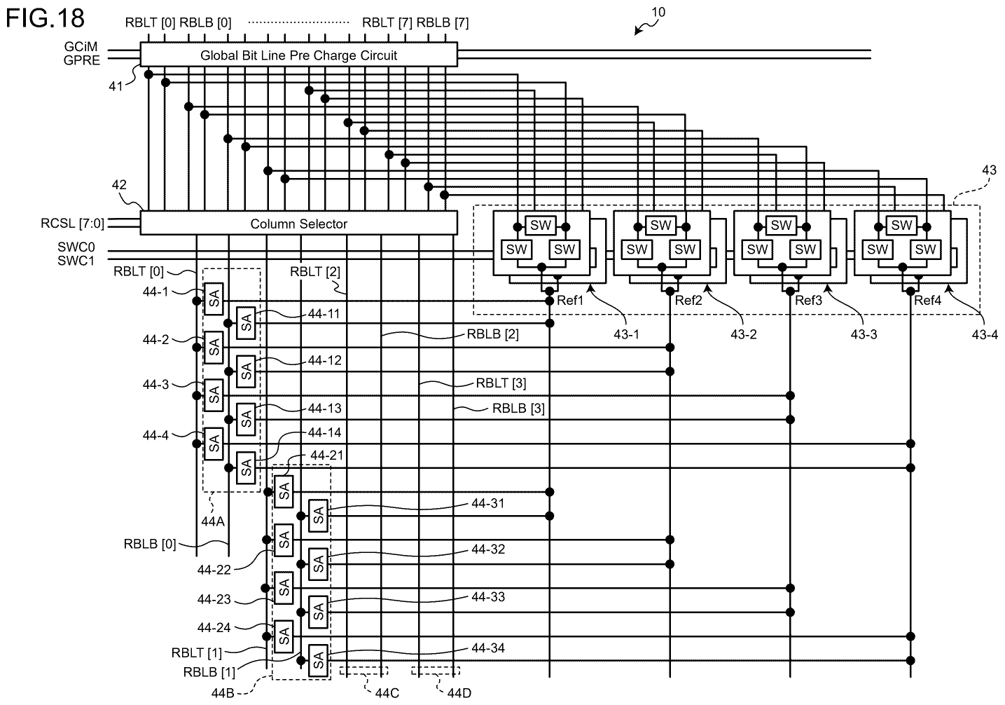

FIG. 18 is an explanatory diagram of a second connection example of the read circuit in the memory device. In FIG. 18, parts similar to those in FIG. 16 are denoted by the same reference numerals, and the detailed description thereof is incorporated. Also in FIG. 18, as in the case of FIG. 16, eight columns (first column to eighth column) (not illustrated) are connected to the global bit line precharge circuit.

The memory device 10 includes a global bit line precharge circuit 41, a column selector 42, a reference voltage generation circuit unit 43, a first sense amplifier unit 44A, a second sense amplifier unit 44B, a third sense amplifier unit 44C, and a fourth sense amplifier unit 44D.

The second connection example in FIG. 18 is different from the first connection example in FIG. 16 in that the first sense amplifier unit 44A, the second sense amplifier unit 44B, the third sense amplifier unit 44C, and the fourth sense amplifier unit 44D are included instead of the sense amplifier unit 44 in FIG. 16, and the load capacitance adjustment unit 45 is not provided. Hereinafter, only differences will be described.

The first sense amplifier unit 44A includes the first sense amplifier 44-1 connected to the first output line LO1 of the column selector 42 (corresponding to the first and fifth columns) corresponding to the first global bit line GBLT(0) and the first global bit line GBLT(4) and having the other end connected to the first reference voltage generation circuit 43-1, and the second sense amplifier 44-2 connected to the first output line LO1 of the column selector 42 (corresponding to the first and fifth columns) corresponding to the first global bit lines GBLT(0) and GBLT(4) and having the other end connected to the second reference voltage generation circuit 43-2.

The first sense amplifier unit 44A includes the third sense amplifier 44-3 connected to the first output line LO1 of the column selector 42 (corresponding to the first and fifth columns) corresponding to the first global bit line GBLT(0) and the first global bit line GBLT(4) and having the other end connected to the third reference voltage generation circuit 43-3, and the fourth sense amplifier 44-4 connected to the first output line LO1 of the column selector 42 (corresponding to the first and fifth columns) corresponding to the first global bit line GBLT(0) and the first global bit line GBLT(4) and having the other end connected to the fourth reference voltage generation circuit 43-4.

The first sense amplifier unit 44A includes a first sense amplifier 44-11 connected to the second output line LO2 of the column selector 42 (corresponding to the first and fifth columns) corresponding to the second global bit lines GBLB(0) and GBLB(4) and having the other end connected to the first reference voltage generation circuit 43-1, and a second sense amplifier 44-12 connected to the second output line L02 of the column selector 42 (corresponding to the first and fifth columns) corresponding to the second global bit lines GBLB(0) and GBLB(4) and having the other end connected to the second reference voltage generation circuit 43-2.

The first sense amplifier unit 44A includes a third sense amplifier 44-13 connected to the second output line LO2 of the column selector 42 (corresponding to the first and fifth columns) corresponding to the second global bit line GBLB(0) and the second global bit line GBLB(4) and having the other end connected to the third reference voltage generation circuit 43-3, and a fourth sense amplifier 44-14 connected to the second output line LO2 of the column selector 42 (corresponding to the first and fifth columns) corresponding to the second global bit line GBLB(0) and the second global bit line GBLB(4) and having the other end connected to the fourth reference voltage generation circuit 43-4.

The second sense amplifier unit 44B includes a first sense amplifier 44-21 connected to the third output line LO3 of the column selector 42 (corresponding to the second and sixth columns) corresponding to the first global bit line GBLT(1) and the first global bit line GBLT(5) and having the other end connected to the first reference voltage generation circuit 43-1, and a second sense amplifier 44-22 connected to the third output line LO3 of the column selector 42 (corresponding to the second and sixth columns) corresponding to the first global bit lines GBLT(1) and GBLT(5) and having the other end connected to the second reference voltage generation circuit 43-2.

The second sense amplifier unit 44B includes a third sense amplifier 44-23 connected to the third output line LO3 of the column selector 42 (corresponding to the second and sixth columns) corresponding to the first global bit line GBLT(1) and the first global bit line GBLT(5) and having the other end connected to the third reference voltage generation circuit 43-3, and a fourth sense amplifier 44-24 connected to the third output line LO3 of the column selector 42 (corresponding to the second and sixth columns) corresponding to the first global bit line GBLT(1) and the first global bit line GBLT(5) and having the other end connected to the fourth reference voltage generation circuit 43-4.

The second sense amplifier unit 44B includes a first sense amplifier 44-31 connected to the fourth output line LO4 of the column selector 42 (corresponding to the second and sixth columns) corresponding to the second global bit lines GBLB(1) and GBLB(5) and having the other end connected to the first reference voltage generation circuit 43-1, and a second sense amplifier 44-32 connected to the fourth output line LO4 of the column selector 42 (corresponding to the second and sixth columns) corresponding to the second global bit lines GBLB(1) and GBLB(5) and having the other end connected to the second reference voltage generation circuit 43-2.

The second sense amplifier unit 44B includes a third sense amplifier 44-33 connected to the fourth output line LO4 of the column selector 42 (corresponding to the second and sixth columns) corresponding to the second global bit line GBLB(1) and the second global bit line GBLB(5) and having the other end connected to the third reference voltage generation circuit 43-3, and a fourth sense amplifier 44-34 connected to the fourth output line LO4 of the column selector 42 (corresponding to the second and sixth columns) corresponding to the second global bit line GBLB(1) and the second global bit line GBLB(5) and having the other end connected to the fourth reference voltage generation circuit 43-4.

The third sense amplifier unit 44C has the same configuration as the first sense amplifier unit 44A, and although not illustrated, includes a first sense amplifier connected to the fifth output line LO11 of the column selector 42 (corresponding to the third and seventh columns) corresponding to the first global bit line GBLT(2) and the first global bit line GBLT(6) and having the other end connected to the first reference voltage generation circuit 43-1, and a second sense amplifier connected to the fifth output line LO11 of the column selector 42 (corresponding to the third and seventh columns) corresponding to the first global bit lines GBLT(2) and LBLT(6) and having the other end connected to the second reference voltage generation circuit 43-2.

The third sense amplifier unit 44C includes a third sense amplifier connected to the fifth output line LO11 of the column selector 42 (corresponding to the third and seventh columns) corresponding to the first global bit line GBLT(2) and the first global bit line GBLT(6) and having the other end connected to the third reference voltage generation circuit 43-3, and a fourth sense amplifier connected to the fifth output line LO11 of the column selector 42 (corresponding to the third and seventh columns) corresponding to the first global bit line GBLT(2) and the first global bit line GBLT(6) and having the other end connected to the fourth reference voltage generation circuit 43-4.

The third sense amplifier unit 44C includes the first sense amplifier connected to the sixth output line LO12 of the column selector 42 (corresponding to the third and seventh columns) corresponding to the second global bit lines GBLB(2) and GBLB(6) and having the other end connected to the first reference voltage generation circuit 43-1, and the second sense amplifier connected to the sixth output line LO12 of the column selector 42 (corresponding to the third and seventh columns) corresponding to the second global bit lines GBLB(2) and GBLB(6) and having the other end connected to the second reference voltage generation circuit 43-2.

The third sense amplifier unit 44C includes the third sense amplifier connected to the sixth output line LO12 of the column selector 42 (corresponding to the third and seventh columns) corresponding to the second global bit line GBLB(2) and the second global bit line GBLB(6) and having the other end connected to the third reference voltage generation circuit 43-3, and the fourth sense amplifier connected to the sixth output line LO12 of the column selector 42 (corresponding to the first and fifth columns) corresponding to the second global bit line GBLB(2) and the second global bit line GBLB(6) and having the other end connected to the fourth reference voltage generation circuit 43-4.

The fourth sense amplifier unit 44D has the same configuration as the first sense amplifier unit 44A, and although not illustrated, includes the first sense amplifier connected to the seventh output line LO13 of the column selector 42 (corresponding to the fourth and eighth columns) corresponding to the first global bit line GBLT(3) and the first global bit line GBLT(7) and having the other end connected to the first reference voltage generation circuit 43-1, and the second sense amplifier connected to the seventh output line LO13 of the column selector 42 (corresponding to the fourth and eighth columns) corresponding to the first global bit lines GBLT(3) and LBLT(7) and having the other end connected to the second reference voltage generation circuit 43-2.

The fourth sense amplifier unit 44D includes the third sense amplifier connected to the seventh output line LO13 of the column selector 42 (corresponding to the fourth and eighth columns) corresponding to the first global bit line GBLT(3) and the first global bit line GBLT(7) and having the other end connected to the third reference voltage generation circuit 43-3, and the fourth sense amplifier connected to the seventh output line LO13 of the column selector 42 (corresponding to the fourth and eighth columns) corresponding to the first global bit line GBLT(3) and the first global bit line GBLT(7) and having the other end connected to the fourth reference voltage generation circuit 43-4.

The fourth sense amplifier unit 44D includes the first sense amplifier connected to the eighth output line LO14 of the column selector 42 (corresponding to the fourth and eighth columns) corresponding to the second global bit lines GBLB(3) and GBLB(7) and having the other end connected to the first reference voltage generation circuit 43-1, and the second sense amplifier connected to the eighth output line LO14 of the column selector 42 (corresponding to the fourth and eighth columns) corresponding to the second global bit lines GBLB(3) and GBLB(7) and having the other end connected to the second reference voltage generation circuit 43-2.

The fourth sense amplifier unit 44D includes the third sense amplifier connected to the eighth output line LO14 of the column selector 42 (corresponding to the fourth and eighth columns) corresponding to the second global bit line GBLB(3) and the second global bit line GBLB(7) and having the other end connected to the third reference voltage generation circuit 43-3, and the fourth sense amplifier connected to the eighth output line LO14 of the column selector 42 (corresponding to the fourth and eighth columns) corresponding to the second global bit line GBLB(3) and the second global bit line GBLB(7) and having the other end connected to the fourth reference voltage generation circuit 43-4.

According to the connection state of the read circuit having the above configuration, the first sense amplifiers 44-1, 44-11, 44-21, and 44-31, the second sense amplifiers 44-2, 44-12, 44-22, and 44-32, the third sense amplifiers 44-3, 44-13, 44-23, and 44-33, and the fourth sense amplifiers 44-4, 44-14, 44-24, and 44-34 are connected to the first reference voltage generation circuit 43-1 to the fourth reference voltage generation circuit 43-4, and the first reference voltage Ref1 to the fourth reference voltage Ref4 generated in the reference voltage generation circuit 43-1 to the fourth reference voltage generation circuit 43-4 are generated by short-circuiting the corresponding first global bit line GBLT and the corresponding second global bit line GBLB. Thus, eight sense amplifiers are connected to one reference voltage supply line.

Therefore, when the charge sharing operation is performed, the difference in parasitic load between the first global bit line GBLT and the second global bit line GBLB can be canceled, the gradient of the potential level of the first global bit line GBLT and the gradient of the potential level of the second global bit line GBLB illustrated in FIGS. 15A and 15B can be matched with the gradient of the reference voltage, and by the charge sharing operation, the influence of the manufacturing variation of the semiconductor integrated circuit is removed, the error of the reference voltage (in the case of the above example, the first reference voltage to the fourth reference voltage) used for data reading is further reduced, and data reading can be performed more accurately and reliably.

According to the first embodiment, in the semiconductor integrated circuit that controls the potential level using the charge sharing, the variation in the read current can be suppressed, and moreover, in the semiconductor integrated circuit including the SRAM bit cell, the product-sum operation can be performed on the semiconductor integrated circuit.

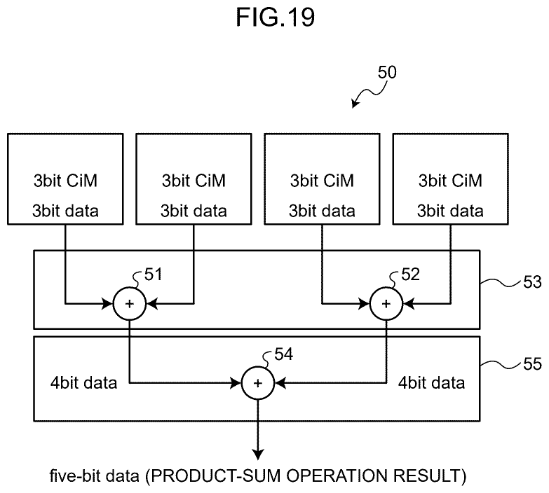

The product-sum operation performed in the above embodiment will be described. FIG. 19 is a schematic explanatory diagram of a product-sum operation circuit of a digital method. A product-sum operation circuit 50 includes a first addition unit 53 including two four-bit adders 51 and 52 and a second addition unit 55 including one five-bit adder 54.

In the example of FIG. 18, it is assumed that four memory array blocks operate in the CiM mode, and three-bit multiplication result (product) data is obtained. Then, the four memory array blocks are divided into two groups each including two and added by four-bit adders 51 and 52 of the first addition unit 53 to obtain four-bit addition result data.

Two pieces of four-bit addition result data obtained as a result are further added by the five-bit adder 54 of the second addition unit 55, whereby a five-bit product-sum operation result is obtained. In this way, it is possible to easily cope with the product-sum operation of the multi-bit number by combining the addition units of the digital method.

In the above configuration, multiple bits may be simultaneously output via plural sense amplifier circuits when performing a product-sum operation of a multi-bit number or when outputting a product-sum operation result. The above description is about the product-sum operation circuit of the digital method, whereas it is possible to perform the product-sum operation of the analog method in which the voltage value is added in an analog manner and analog/digital conversion is performed although the detection accuracy decreases. Also in this case, the effect of improving accuracy by charge sharing can be obtained.

### (2) Second Embodiment

Next, the second embodiment will be described. First, problems to be solved by the second embodiment will be described. In a conventional charge collector (bit line capacitance sharing) circuit, when a CiM operation (charge sharing of plural banks) is performed, there is a possibility that a local bit line pair is short-circuited depending on a bit line potential situation and a potential is shared.

This is because the existing technology assumes the charge sharing operation of only one bank, the charge sharing operation of banks is unexpected, the potential of the bit line pair changes during the CiM operation (during the charge sharing operation), the bit line capacitance sharing circuits of both the bit line pair are connected, and the bit line pair is short-circuited, and a desired operation cannot be performed.

Therefore, an object of the second embodiment is to provide a semiconductor integrated circuit capable of correctly operating even when charge sharing of banks is performed.

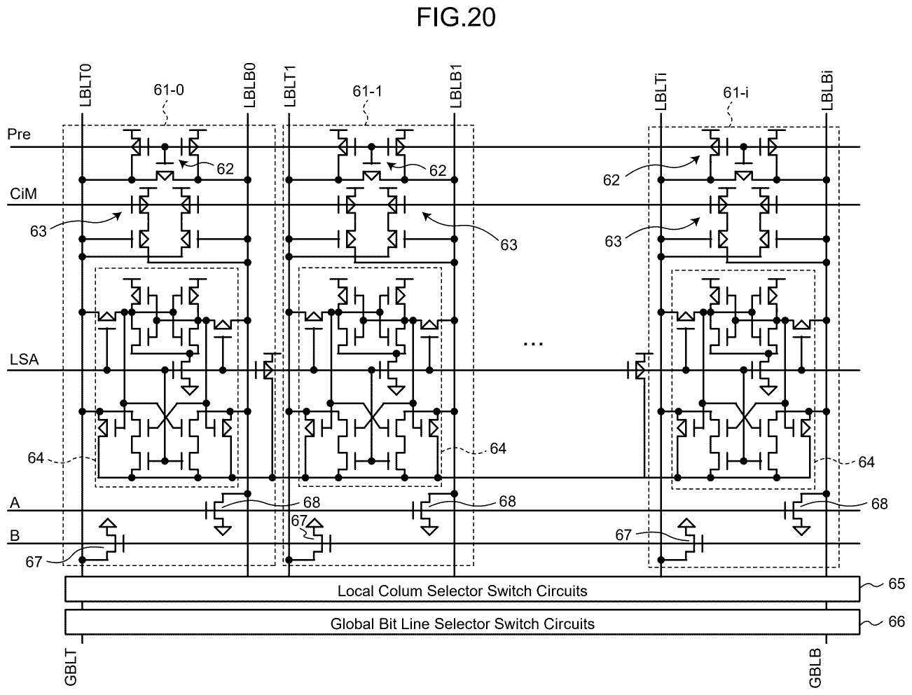

FIG. 20 is an explanatory diagram of a specific circuit configuration of a data reading part of the memory cell array in the memory device of the second embodiment. In FIG. 20, cell array blocks 61-0 to 61-n corresponding to (n+1) (n: an integer of 2 or more) columns are illustrated. In this case, since the cell array block 61-0 to the cell array block 61-n have the same configuration, the cell array block 61-0 will be described as an example.

The cell array block 61-0 includes a cell array (not illustrated), a precharge auxiliary circuit 62, an operation mode switching circuit 63, a latch circuit 64, a local column selector 65, a global bit line selector 66, a reference potential generation data setting circuit 67, and a data reset circuit 68.

The selected memory cell of the cell array (not illustrated) is connected to the first local bit line LBLT0 and the second local bit line LBLB0. The precharge auxiliary circuit 62 discharges the charge corresponding to the fluctuation in the bit line potential in a state where the first local bit line LBLT0 and the second local bit line LBLB0 are short-circuited at the time of precharge.

The operation mode switching circuit 63 sets the operation mode to either a normal mode in which the selected column is read/written from and to the memory cell as usual or a CiM mode in which the product-sum operation is performed based on the data of the memory cells.

As a result, in the normal mode, the target memory cell is connected to the first global bit line GBLT and the second global bit line GBLB via the first local bit line LBLT and the second local bit line LBLB, and the read processing or the write processing is performed.

In addition, in the CiM mode, a product-sum operation is performed on data of target memory cells, and a product-sum operation result is output to the read circuit RC via the first global bit line GBLT and the second global bit line GBLB selected by the global bit line selector 66.

The latch circuit 64 latches and holds the “H”/“L” state before the operation so as not to change the connection state of the shared circuit during the CiM operation. The column selector 65 selects a column from which data is to be read or a column on which the product-sum operation is to be performed from among (n+1) columns corresponding to the cell array block 61-0 to the cell array block 61-n, and connects the selected column to the global bit line selector 66.

The global bit line selector 66 selects and connects the first global bit line GBLT and the second global bit line GBLB. The reference potential generation data setting circuit 67 sets data for generating a reference potential in the memory cell array.

When the cell array block is a non-operation block, the data reset circuit 68 sets “0” data to the memory cell and performs reset. According to the above configuration, even when charge sharing of banks is performed, correct operation can be performed.

### (2.1) First Modification of Second Embodiment

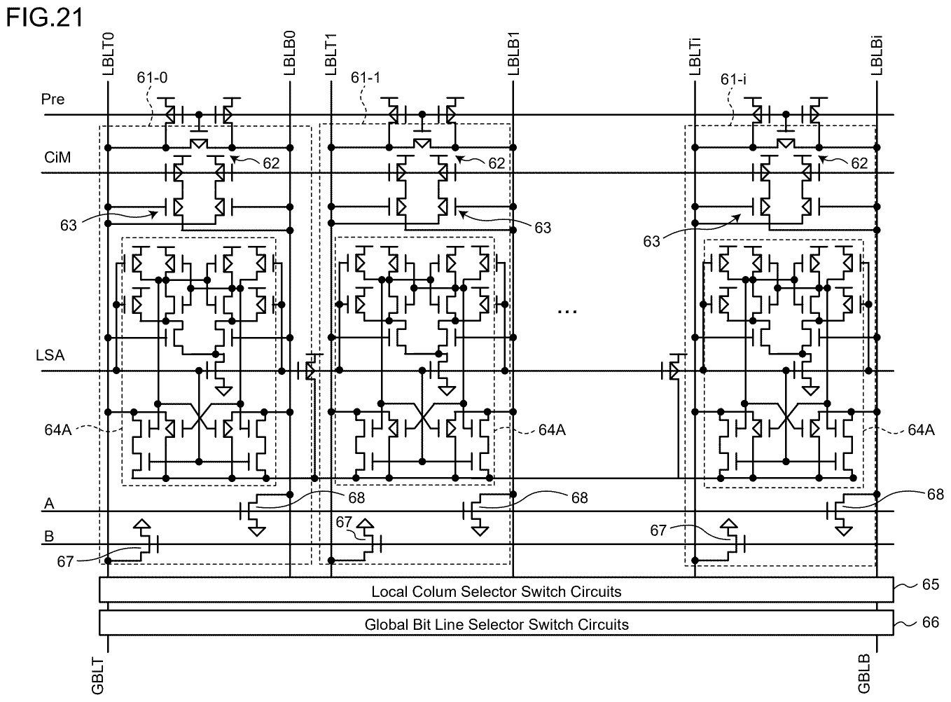

FIG. 21 is an explanatory diagram of a first modification of the second embodiment. The first modification of the second embodiment in FIG. 21 is different from the second embodiment in FIG. 20 in that a latch circuit 64A having a different configuration is provided instead of the latch circuit 64. According to this configuration, the same effects as those of the second embodiment can be obtained.

### (2.2) Second Modification of Second Embodiment

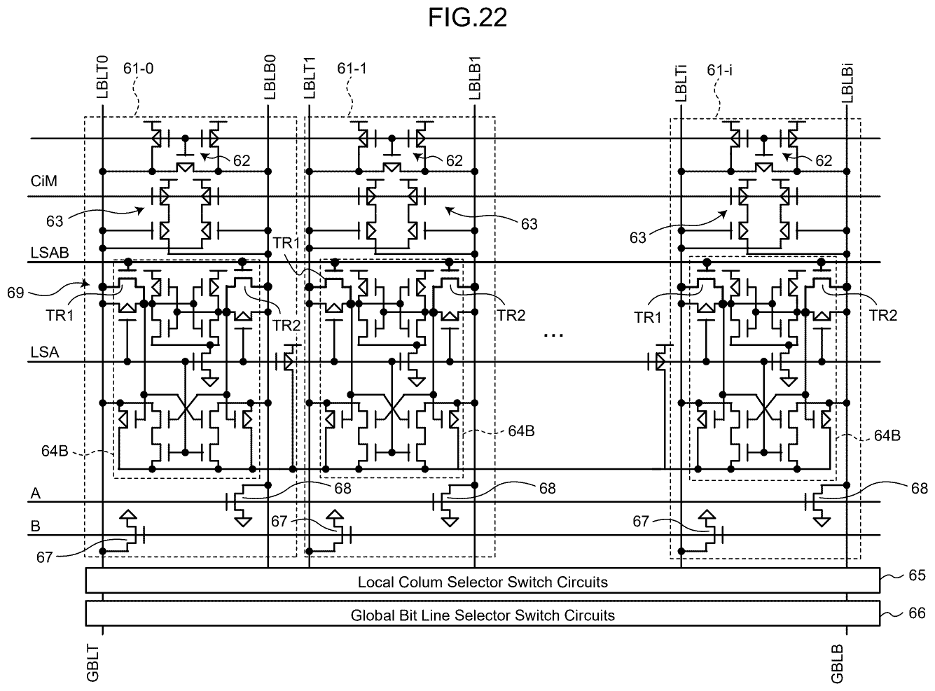

FIG. 22 is an explanatory diagram of a second modification of the second embodiment. The second modification of the second embodiment in FIG. 22 is different from the second embodiment in FIG. 20 in that a latch circuit 64B that also functions as a boost circuit is provided by adding a read boost circuit 69 that improves a signal rising/falling speed and improves a reading speed to the configuration of the latch circuit 64.

The read boost circuit 69 includes a pair of transistors TR1 and TR2, and is brought into a conductive state by a boost read control signal LSA2 at the time of data reading to promote current supply and improve a rising/falling speed of the signal. According to this configuration, in addition to the effects of the second embodiment, an improvement in the data reading speed can be obtained.

### (2.3) Operation of Second Embodiment

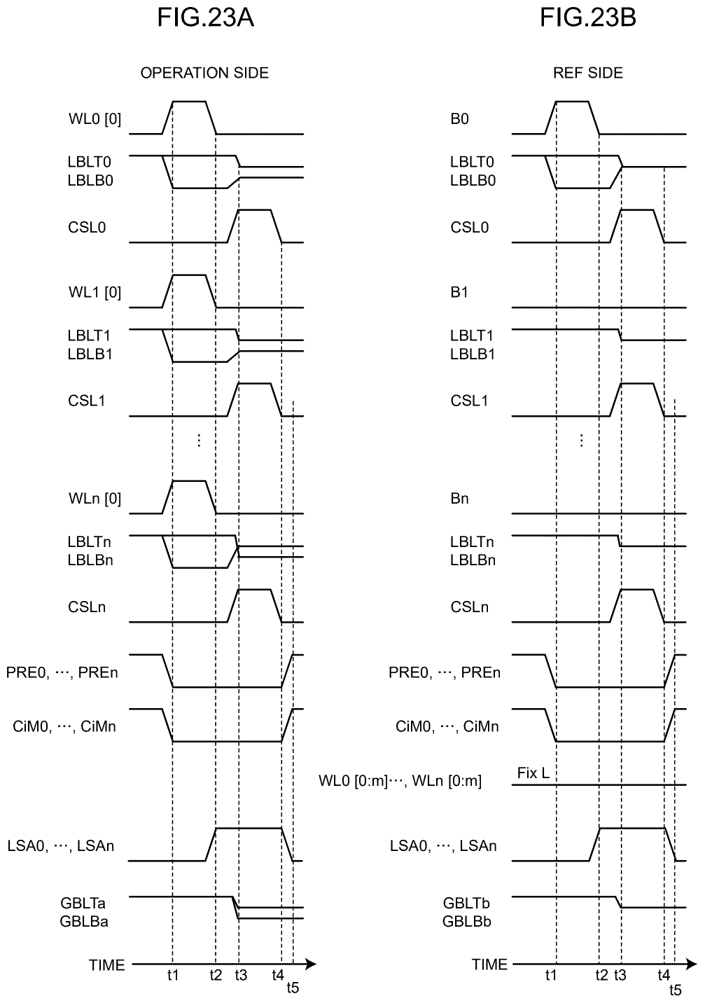

Next, a specific operation will be described. FIG. 23A is an operation timing chart of the operation side column in the CiM mode of the circuit of FIG. 21.

FIG. 23B is an operation timing chart of the generation side column of the reference potential in the CiM mode of the circuit of FIG. 21.

In the operation side column in the CiM mode, as illustrated in FIG. 23A, at time t1, the word line WL corresponding to the memory cell that actually performs the operation transitions to the “H” level, and the first local bit line LBLT or the second local bit line LBLB transitions to the “L” level according to the data held by the memory cell to which the memory cell corresponding to the word line WL is connected.

In addition, the precharge enable lines PRE0 to PREn transition to the “L” level, and the precharge ends.

Further, the operation mode switching lines CiM0 to CiMn transition to the “L” level, and the operation mode transitions to the CiM mode.

On the other hand, in the reference potential generation side column, as illustrated in FIG. 23B, at time t1, the data setting lines B0 to Bn corresponding to the memory cells for actually generating the reference potential transition to the “H” level, and the corresponding memory cells transition to the “L” level.

In addition, the precharge enable lines PRE0 to PREn transition to the “L” level, and the precharge ends. Further, the operation mode switching lines CiM0 to CiMn transition to the “L” level, and the operation mode transitions to a reference potential supply mode corresponding to the CiM mode.

Thereafter, at time t2, the word line WL transitions to the “L” level. In addition, boost read control signals LSA0 to LSAn transition to the “H” level, and the latch circuit 64 captures data.

When the column select lines CSL1 to CSLn transition to the “H” level at time t3, in the operation side column, the first local bit line LBLT and the second local bit line LBLB corresponding to the memory cell that actually performs the operation transition to a predetermined level corresponding to the operation result via the latch circuit 64.

As a result, each of the first global bit line GBLT and the second global bit line GBLB of the operation side column transitions to a level corresponding to the operation result of the operation side column, and the operation result is output.

On the other hand, in the reference potential generation side column, the first local bit line LBLT and the second local bit line LBLB corresponding to the memory cell that generates the reference potential enter the charge sharing state, transition to the same predetermined level corresponding to the value of the reference potential, and output of the reference potential is performed.

Thereafter, when the column select lines CSL1 to CSLn transition to the “L” level at time t4, the precharge enable lines PRE0 to PREn transition to the “H” level in the operation side column at time t5, and the precharge is started.

Further, the operation mode switching lines CiM0 to CiMn transition to the “H” level, the operation mode transitions to the normal mode, and the process ends.

On the other hand, in the reference potential generation side column, when the column select lines CSL1 to CSLn transition to the “L” level at time t4, the precharge enable lines PRE0 to PREn transition to the “H” level at time t5, and the precharge is started.

Further, the operation mode switching lines CiM0 to CiMn transition to the “H” level, the operation mode transitions to the normal mode, and the process ends. As described above, the memory device can correctly operate even when the charge sharing of banks is performed in the semiconductor integrated circuit including the SRAM bit cell, can generates a highly reliable reference potential, and can perform a product-sum operation with high reliability on the semiconductor integrated circuit.

### (2.4) Effects of Second Embodiment

Here, effects of the second embodiment will be described.

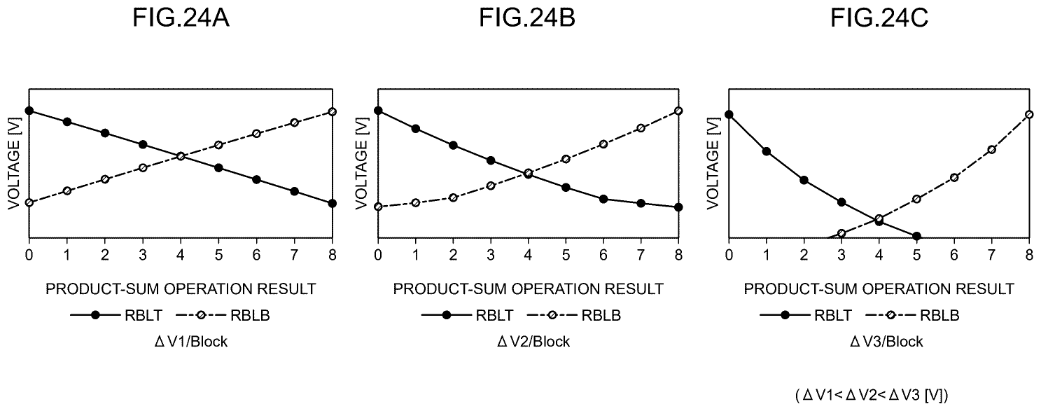

FIG. 24A is an explanatory diagram of a potential difference between the potential of the first global bit line GBLT and the potential of the second global bit line GBLB per local block in a case where the charge collector circuit is not used in the eight-bit CiM.

FIG. 24B is an explanatory diagram of a potential difference between the potential of the first global bit line GBLT and the potential of the second global bit line GBLB per local block in a case where bit line sharing is performed between two columns using a charge collector circuit in eight-bit CiM.

FIG. 24C is an explanatory diagram of a potential difference between the potential of the first global bit line GBLT and the potential of the second global bit line GBLB per local block in a case where bit line sharing is performed between four columns using a charge collector circuit in eight-bit CiM.

In FIGS. 24A to 24C, the vertical axis represents the potential of the first global bit line GBLT or the potential of the second global bit line GBLB with the unit of V.

The horizontal axis represents the value (0 to 8) of the stored data of the local block.

In this case, the bit line potential VBL which is the potential of the first global bit line GBLT or the potential of the second global bit line GBLB is obtained by the following expression when the capacitance of the local bit line is LBC, the capacitance of the global bit line is GBC, and the power supply voltage is PWV.

VBL=(1−(LBC/(GBC+LBC))×PWV

As illustrated in FIG. 24A, the potential difference between the potential of the first global bit line GBLT and the potential of the second global bit line GBLB per local block when the charge collector circuit is not used is ΔV1(V).

On the other hand, as illustrated in FIG. 24B, the potential difference between the potential of the first global bit line GBLT and the potential of the second global bit line GBLB per local block when bit line sharing is performed between two columns using the charge collector circuit is ΔV2(V)(>ΔV1(V)).

Moreover, as illustrated in FIG. 24C, the potential difference between the potential of the first global bit line GBLT and the potential of the second global bit line GBLB per local block in a case where bit line sharing is performed between the four columns using the charge collector circuit is ΔV3(V)(>ΔV2(V)>ΔV1(V)).

That is, it can be seen that the potential difference between the potential of the first global bit line GBLT and the potential of the second global bit line GBLB per local block can be increased as the sharing target and the number of bit lines are increased.

As described above, it has been found that the bit line potential difference per local block increases by increasing the number of shared columns.

### (2.5) Specific Example in which Memory Cell of Second Embodiment is Present

### (2.5.1.) First Configuration Example

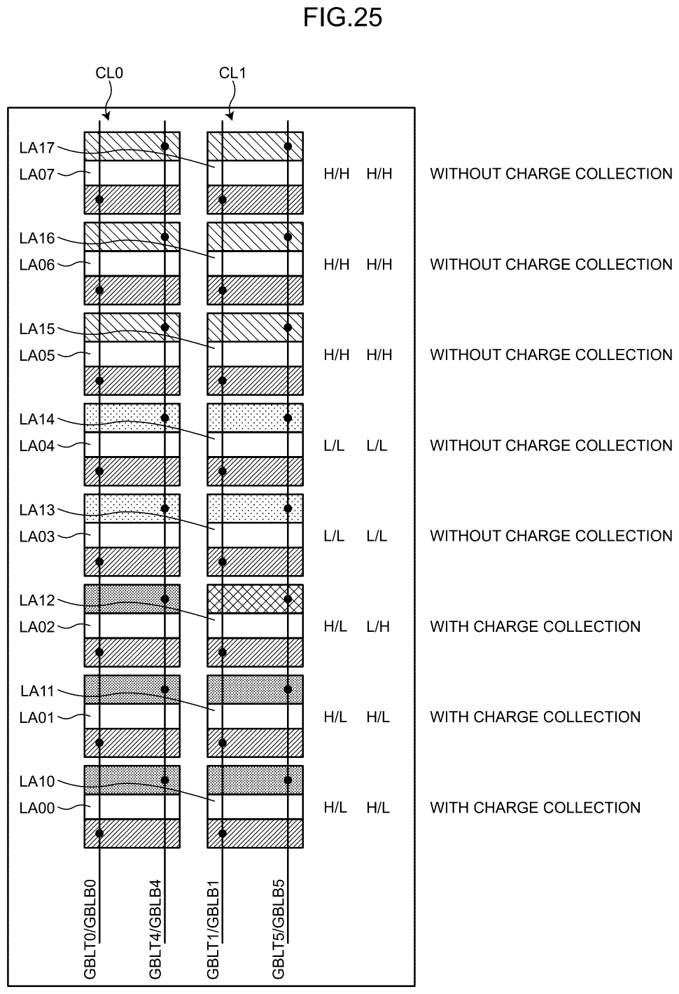

FIG. 25 is an explanatory diagram of a first configuration example of the memory cell array in a case where eight-bit CiM is performed. FIG. 25 illustrates an example of a case where there are two columns in which eight memory cell arrays are connected in series.

The column C0 includes a local array LA_00 to a local array LA_07. In addition, the column C1 includes a local array LA_10 to a local array LA_17.

In FIG. 25, for example, the description “H/H L/H” in the right frames of the local array LA_02 and the local array LA_12 means that the potential level of the first local bit line LBLT of the local array LA_02 is at the “H” level, the potential level of the second local bit line LBLB of the local array LA_02 is at the “H” level, the potential level of the first local bit line LBLT of the local array LA_12 is at the “L” level, and the potential level of the second local bit line LBLB of the local array LA_12 is at the “H” level.

Moreover, in FIG. 25, for example, the description “with charge collector” outside the right frames of the local array LA_02 and the local array LA_12 indicates that bit line sharing is performed between two columns using a charge collector circuit in the local array LA_02 and the local array LA_12.

In FIG. 25, the reason why there are parts in which bit line sharing is performed between two columns and parts in which bit line sharing is not performed between two columns is to clearly identify a difference between two target local arrays in a case where they are at different levels.

As a result, it is not necessary to connect global bit lines for reference potential generation, and different reference potentials can be generated in the first global bit line GBLT and the second global bit line GBLB. Therefore, data can be reliably read with a small area, and a product-sum operation result can be correctly acquired.

### (2.5.2) Second Configuration Example

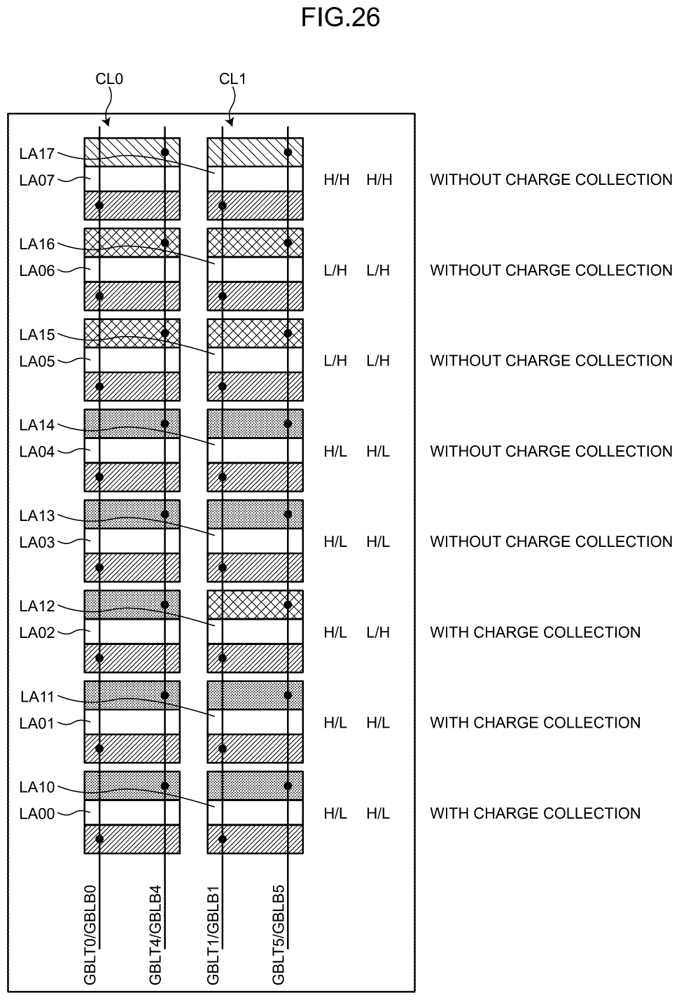

FIG. 26 is an explanatory diagram of a second configuration example of the memory cell array in a case where eight-bit CiM is performed.

FIG. 26 illustrates an example of a case where there are two columns in which eight memory cell arrays are connected in series. The column C0 includes a local array LA_00 to a local array LA_07. In addition, the column C1 includes a local array LA_10 to a local array LA_17.

Also in the case of FIG. 26, as in the case of FIG. 25, it is not necessary to connect global bit lines for reference potential generation, and different reference potentials can be generated in the first global bit line GBLT and the second global bit line GBLB. Therefore, data can be reliably read with a small area, and a product-sum operation result can be correctly acquired.

### (2.5.3) Third Configuration Example

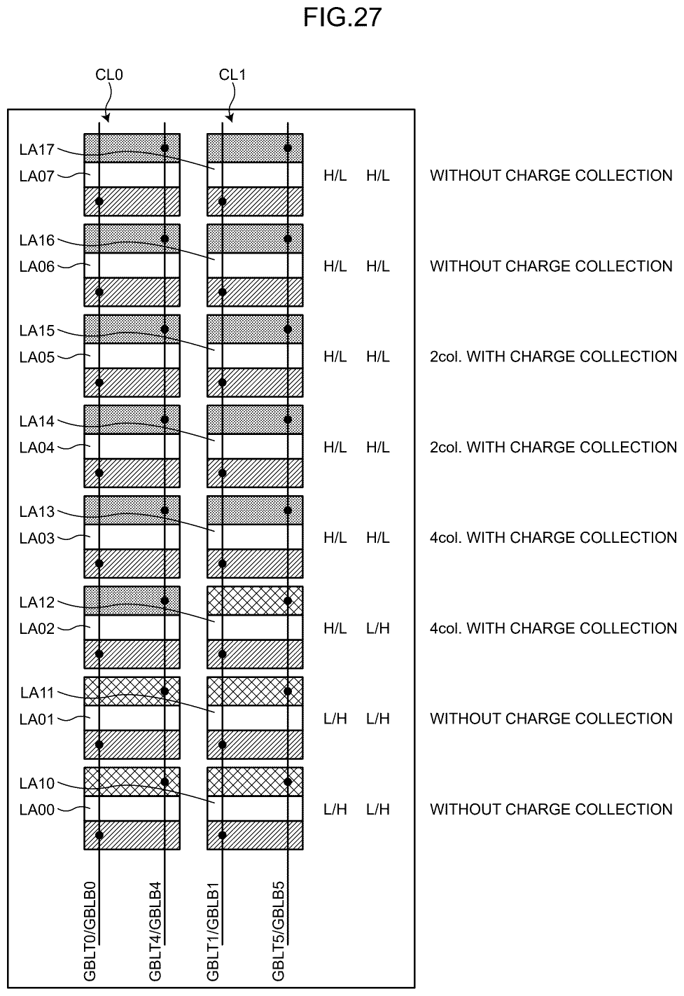

FIG. 27 is an explanatory diagram of a third configuration example of the memory cell array in a case where eight-bit CiM is performed. The example of FIG. 27 is different from the above configuration example in that a case where bit line sharing is performed between two columns using a charge collector circuit as in the cases of FIGS. 25 and 26, and a case where bit line sharing is performed between four columns using two adjacent columns (not illustrated) are included.

The column C0 includes a local array LA_00 to a local array LA_07. In addition, the column C1 includes a local array LA_10 to a local array LA_17.

In FIG. 25, for example, the description “with charge collection” outside the right frames of the local array LA_02 and the local array LA_12 indicates that bit line sharing is performed between two columns using a charge collector circuit in the local array LA_02 and the local array LA_12.

In FIG. 27, the reason why there are parts in which bit line sharing is performed between four columns, parts in which bit line sharing is performed between two columns, and parts in which bit line sharing is not performed between two columns is to make the level difference between two target local arrays clearer. As a result, it is not necessary to connect the global bit lines for reference potential generation, and different reference potentials can be generated in the first global bit line GBLT and the second global bit line GBLB. Therefore, data can be reliably read with a small area, and a product-sum operation result can be correctly acquired.

### (3) Third Embodiment

Next, the third embodiment will be described. First, problems to be solved by the third embodiment will be described.

As described above, although it is possible to improve the signal amplitude of the global bit line by adopting the charge sharing type configuration, it is necessary to provide a latch circuit that latches the “H” level/“L” level state before the operation for each bit line so as not to change the connection state of the sharing circuit during the CiM operation, the circuit installation area increases, and it is difficult to provide a configuration with a small area.

In addition, in a case where the target bit cell is of a high-density type, the configuration in which the latch circuit is provided for each bit line increases a degree of the area increase, and thus it is necessary to suppress the area increase due to the provision of the latch circuit via the local column selector.

However, by providing the local column selector, there is a concern that the write characteristics are deteriorated. Therefore, an object of the third embodiment is to provide a semiconductor integrated circuit capable of obtaining a signal amplitude of a bit line equivalent to that in a case where charge sharing is performed, without performing charge sharing.

When the charge collector technology is used as illustrated in FIGS. 24A to 24C, the bit line potential VBL which is the potential of the first global bit line GBLT or the potential of the second global bit line GBLB is obtained by the following expression when the capacitance of the local bit line is LBC, the capacitance of the global bit line is GBC, and the power supply voltage is PWV.

$$VBL = ( 1 - ( LBC / ( GBC + LBC ) ) \times PWV$$

According to the expression above, it can be seen that the charge collector technology improves the signal amplitude of the global bit line by increasing the size of the numerator of this expression. Therefore, from this expression, it can be seen that, in order to improve the signal amplitude of the global bit line, the signal amplitude of the global bit line can be improved by reducing the denominator of this expression.

That is, the sum of the capacitance LBC of the local bit line and the capacitance GBC of the global bit line may be reduced.

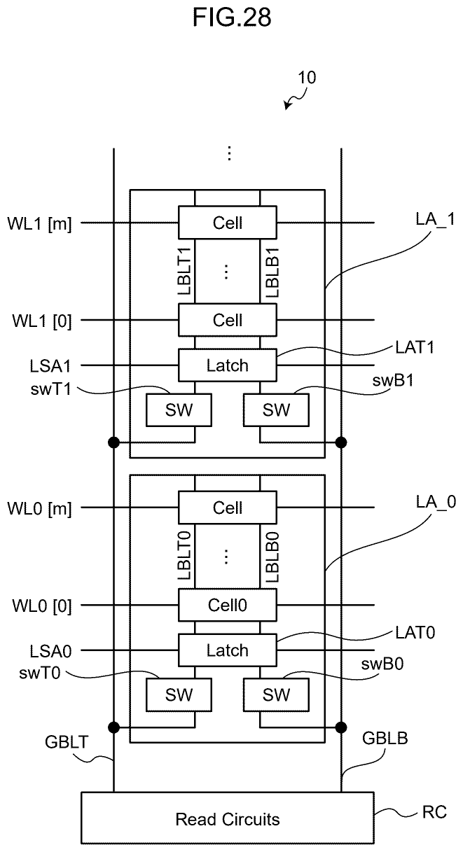

FIG. 28 is an explanatory diagram of a main part of a memory device to which the third embodiment is applied. A memory device 10A includes n+1 (n is an integer of 2 or more) local arrays LA_0 to LA_n, the first global bit line GBLT, the second global bit line GBLB, and the read circuit RC.

Each local array LA_x includes the first local bit line LBLTx, the second local bit line LBLBx, memory cells Cell0 to Celln, the latch circuit LAT, the first switch swTx, and the second switch swBx.

In the above configuration, each of the memory cells Cell0 to Celln is connected between the first local bit line LBLTx and the second local bit line LBLBx. The first local bit line LBLTx is connected to the read circuit RC via the latch circuit LAT and the first switch swTx.

Further, the second local bit line LBLBx is connected to the read circuit RC via the latch circuit LAT and the second switch swBx.

Moreover, the first switch swTx and the second switch swBx are turned on in a case where the corresponding local array LA_x is selected by the column selection line CSL(x) according to the state of the local bit line, and connect the first local bit line LBLTx being in the “L” state to the global bit line GBLT corresponding to the first local bit line LBLTx, and connect the second local bit line LBLBx to the second global bit line GBLB.

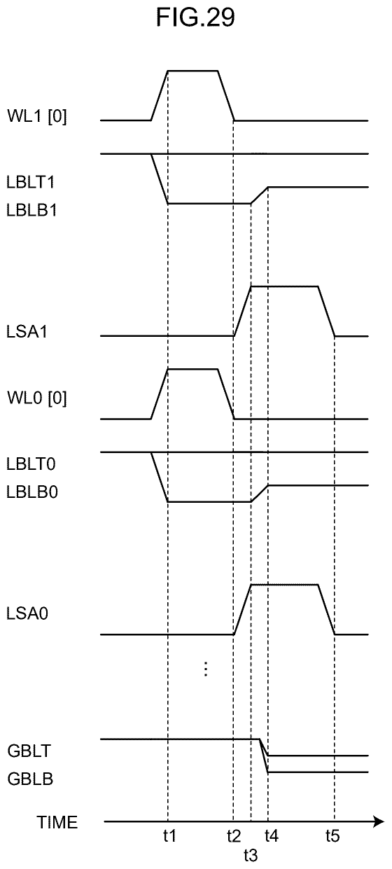

Next, an operation of the third embodiment will be described. FIG. 29 is an operation timing chart of the operation side column in the CiM mode of the circuit of FIG. 28.

In the operation side column in the CiM mode, as illustrated in FIG. 29, at time t1, the word lines WL0(0) to WL1(0) corresponding to the memory cell that actually performs the operation transition to the “H” level, and the corresponding local bit line transitions to the “L” level according to the data held by the memory cells. In this state, the operation mode shifts to the CiM mode.

Thereafter, at time t2, the word lines WL0(0) to WL1(0) transition to the “L” level. When the boost read control signals LSA0 to LSA1 transition to the “H” level at time t3, in the operation side column, at time t4, the first local bit lines LBLT0 and LBLT1 and the second local bit lines LBLB0 and LBLB1 corresponding to the memory cell that actually performs the operation transition to predetermined levels corresponding to the operation results. Thereafter, at time t5, the boost read control signals LSA0 to LSA1 transition to the “L” level.

In this case, in the third embodiment, in the first local bit line LBLT and the second local bit line LBLB corresponding to the memory cell that actually performs the operation, only the first local bit line LBLT or the second local bit line LBLB at the “L” level is connected to the first global bit line GBLT and the second global bit line GBLB, and the first local bit line LBLT and the second local bit line LBLB at the “H” level are not connected to the first global bit line GBLT and the second global bit line GBLB.

On the other hand, in the conventional example in which only the first local bit line LBLT and the second local bit line LBLB corresponding to all the memory cells on which the product-sum operation is to be performed are connected to the first global bit line GBLT and the second global bit line GBLB, it is necessary to perform charge sharing in the state of the first local bit line LBLT at “H” level and the second local bit line LBLB at “H” level. In addition, since this state is a so-called floating state, measures against coupling noise are required due to various signal transitions.

On the other hand, in the third embodiment, since the above state does not occur in principle, the conventional circuit can be used or shared, and the affinity with the operation mode of the normal mode is increased.

As a result, it is not necessary to provide the latch circuit for each bit line, it is possible to reduce the circuit installation area, and the circuit can be configured with a small area.

In addition, even in a case where the target bit cell is of a high-density type, it is not necessary to provide a latch circuit for each bit line, and it is not necessary to provide a local column selector. Therefore, deterioration of write characteristics is not caused.

### (4) Fourth Embodiment

Next, the fourth embodiment will be described. First, problems to be solved by the fourth embodiment will be described.

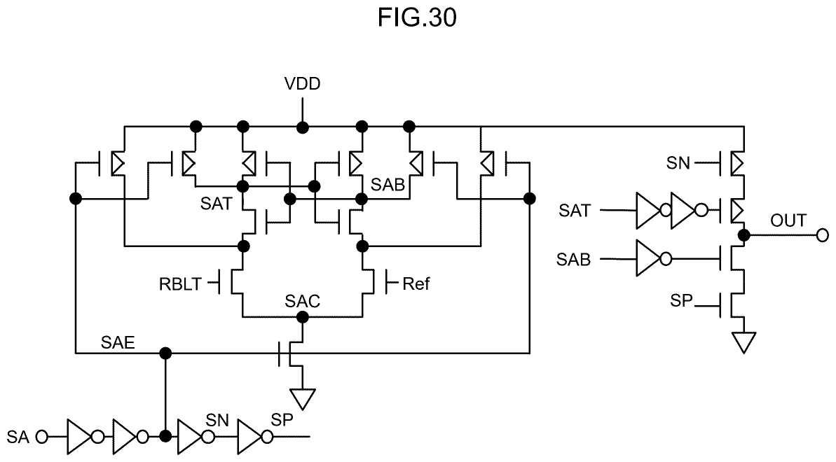

FIG. 30 is an explanatory diagram of an exemplary circuit of a conventional latch-type determination circuit. When the potential between the source-drain terminals of the transistors constituting the differential input unit (RBLT, Ref) transitions from the initial value intermediate potential or the power supply potential to a low-potential-side power supply VSS potential at the timing of rising of a sense amplifier enable signal SAE, the gate potential of the differential input unit also decreases due to coupling noise.

Therefore, in a case where the CiM operation is performed, the potential of the bit line varies depending on the state of the data for operation, and the influence of the coupling noise is not constant. Therefore, there is a possibility that the CiM operation itself is not an assumed operation.

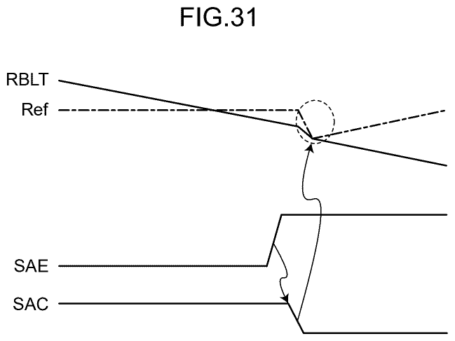

FIG. 31 is an explanatory diagram of a signal state of each unit of a conventional latch-type determination circuit. For example, in a case where the reference potential Ref fluctuates depending on the state of the data for operation, and the determination is made in a state where there is no potential difference as illustrated in a broken-line circle of FIG. 31, there is a possibility that the determination of the input bit line potential RBLT is erroneous determination.

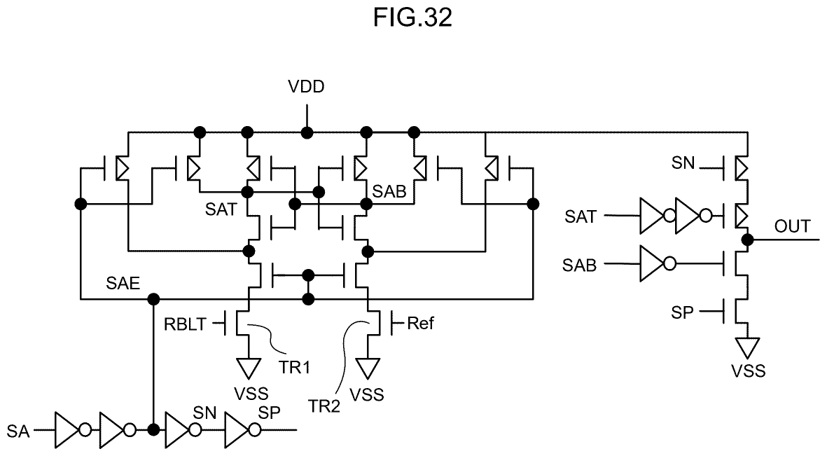

FIG. 32 is an explanatory diagram of an exemplary circuit of the latch-type determination circuit according to the fourth embodiment. As illustrated in FIG. 32, by setting the initial potential of the source-drain terminals of the transistors TR1 and TR2 constituting the differential input unit to a low-potential-side power supply potential VSS, the power supply fluctuation during the operation of the transistors TR1 and TR2 is reduced, and the influence of the coupling noise is suppressed.

In this case, it is considered that the offset voltage due to manufacturing variations of the transistors TR1 and TR2 increases. However, in the fourth embodiment, by increasing the sizes of the transistors TR1 and TR2, the offset voltage can be reduced, and moreover, the effect of reducing the power supply fluctuation during the operation of the transistors TR1 and TR2 and suppressing the influence of the coupling noise can be greatly obtained.

### (5) Fifth Embodiment

The fifth embodiment is an embodiment in which noise fluctuation due to restriction of physical arrangement is suppressed in a case where plural data read circuits for performing read determination are provided, and the correct read determination can be made. The lower the potential level, the smaller the potential difference (read margin) between the read bit line (global bit line) and the reference bit line.

Therefore, in the fifth embodiment, the data read circuit that makes the read determination using the reference bit line potential assumed to have a smaller read margin is disposed in a place that is less susceptible to the influence of noise fluctuation.

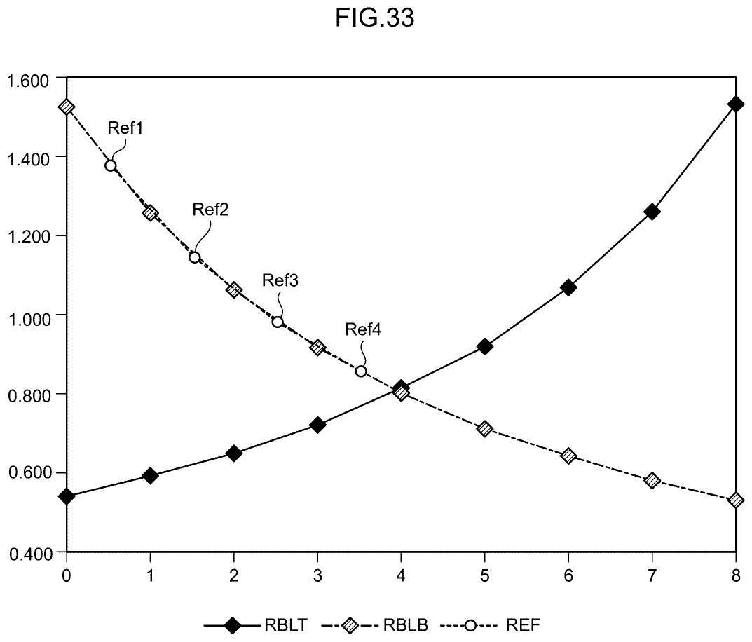

This will be described in more detail below. FIG. 33 is a diagram illustrating potential simulation results of the global bit line and the reference bit line. As illustrated in FIG. 33, the gradient of the potential level curve of the global bit line decreases as the potential level decreases. Therefore, it can be seen that the lower the potential level, the smaller the potential difference between the global bit lines RBLT and RBLB and the reference bit line REF, and the smaller the read margin. The fact that the read margin is reduced means that the place is more susceptible to noise fluctuation. Thus, in the first aspect of the fifth embodiment described below, the data read circuit to which the reference bit line assumed to have a small read margin is connected is disposed at a physical position close to the read circuit drive buffer (disposed so as to move first).

The bit line potential BLV is expressed by the following expression.

$$Bit line potential BLV = ( 1 - ( CLB / ( CGB + CLB ) ) \times PWV$$

CLB is a capacitance of the local bit line, CGB is a capacitance of the global bit line, and PWV is a power supply voltage. Therefore, in the second aspect of the fifth embodiment described below, a circuit that makes a read determination using a reference bit line potential assumed to reduce a read margin is disposed at a place where a wiring load increases.

### (5.1) First Aspect of Fifth Embodiment

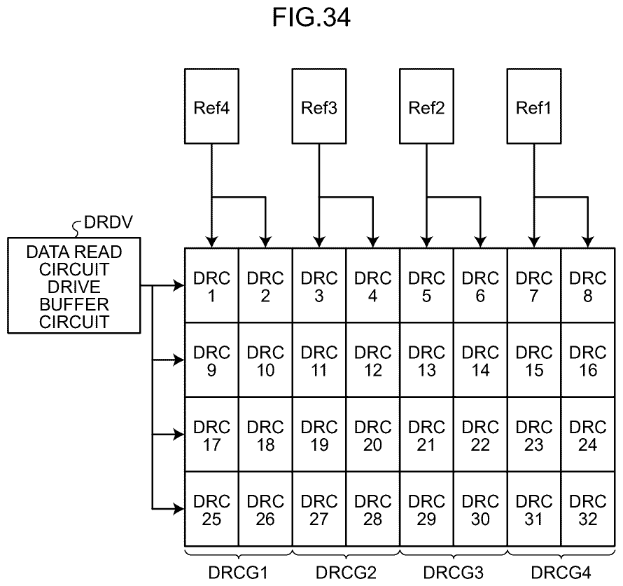

FIG. 34 is an explanatory diagram of a first aspect of the fifth embodiment. FIG. 34 illustrates a case where 32 data read circuits DRC1 to DRC32 for performing 32 value simultaneous reading in a case of performing an eight-bit product-sum operation are provided.

In FIG. 34, a drive signal DRV from the data read circuit drive buffer circuit is supplied in parallel to the eight data read circuits DRC1 to DRC8, the eight data read circuits DRC9 to DRC16, the eight data read circuits DRC17 to DRC24, and the eight data read circuits DRC25 to DRC32.

Therefore, for example, the data read circuits DRC1 to DRC8 sequentially operate in the order of the data read circuit DRC1, the data read circuit DRC2, . . . , the data read circuit DRC7, and the data read circuit DRC8, under the influence of the wiring load caused by the wiring length.

As described above, since the read margin is smaller as the reference bit line potential is lower, the read margin is more susceptible to noise fluctuation, and thus the operation is started earlier by disposing the circuit at a position physically closer to the data read circuit drive buffer circuit.

Therefore, in the case of the example in FIG. 34, the reference potential Ref4 is supplied to a read circuit group DRCG1 that is disposed at a position physically closest to the data read circuit drive buffer circuit DRDV and is driven first.

Then, the reference potential Ref3 is supplied to a read circuit group DRCG2 disposed at a position next physically closest to the data read circuit drive buffer circuit and driven next to the read circuit group DRCG1.

Similarly, the reference potential Ref2 is supplied to the read circuit group DRCG3. Then, the reference potential Ref1 is supplied to a read circuit group DRCG4 that is disposed at a position physically farthest from the data read circuit drive buffer circuit and is driven last.

Therefore, the influence of noise fluctuation caused by the operation of another read circuit can be reduced in the entire read circuit, and correct data reading can be performed.

### (5.2) Second Aspect of Fifth Embodiment

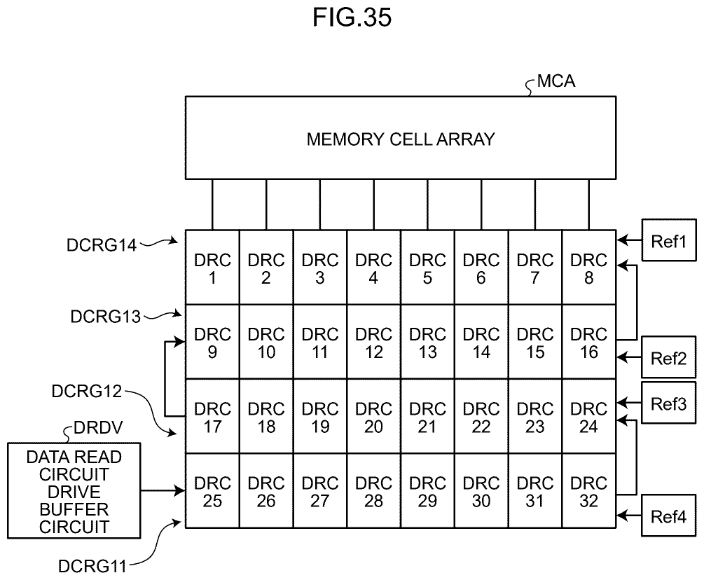

FIG. 35 is an explanatory diagram of the second aspect of the fifth embodiment. FIG. 35 also illustrates a case where 32 data read circuits DRC1 to DRC32 for performing 32 value simultaneous reading in a case of performing an eight-bit product-sum operation are provided.

As described above, the data read circuit to which the reference bit line assumed to have a small read margin is connected is disposed at a position physically close to the read circuit drive buffer (disposed so as to move first). Moreover, the data read circuit to which the reference bit line assumed to have a small read margin is connected is preferably disposed at a position far from the memory cell array.

This is because it is assumed that the bit line potential BLV is high since the wiring load increases as the read circuit is disposed at a position physically farther from the cell array (the capacitance CGB of the global bit line in the above expression increases).

In FIG. 35, the drive signal DRV from the data read circuit drive buffer circuit is supplied in the order of the data read circuit group DRCG11, the data read circuit group DRCG12, the data read circuit group DRCG13, and the data read circuit group DRCG14. Therefore, the data read circuit groups DRCG11 to DRCG14 sequentially operate in the order of the data read circuit group DRCG11, the data read circuit group DRCG12, the data read circuit group DRCG13, and the data read circuit group DRCG14, under the influence of the wiring load caused by the wiring length.

As described above, since the read margin is smaller as the reference bit line potential is lower, the read margin is more susceptible to noise fluctuation, and thus the operation is started earlier by disposing the circuit at a position physically closer to the data read circuit drive buffer circuit.

In addition, since the wiring load increases as the read circuit is disposed at a position physically farther from the memory cell array MCA (the capacitance CGB of the global bit line in the above expression increases), it is assumed that the bit line potential BLV increases.

Therefore, the data read circuit group DRCG11 (i.e., the data read circuits DRC25 to DRC32) disposed at a position physically farthest from the memory cell array MCA is disposed at a position closest to the data read circuit drive buffer circuit, and the reference potential Ref4 having the lowest potential is supplied.

Then, the reference potential Ref3 is supplied to the read circuit group DRCG12 (i.e., the data read circuits DRC17 to DRC24) disposed at a position physically next farthest from the memory cell array MCA and driven next to the read circuit group DRCG11. Similarly, the reference potential Ref2 is supplied to the read circuit group DRCG3 (i.e., the data read circuits DRC9 to DRC16).

Then, the reference potential Ref1 is supplied to the read circuit group DRCG14 (i.e., the data read circuits DRC1 to DRC8) disposed at a position physically closest to the memory cell array MCA and driven last. Therefore, the influence of noise fluctuation caused by the operation of another read circuit can be reduced in the entire read circuit, and correct data reading can be performed.

### (6) Effects of Embodiment

As described above, according to each embodiment, it is possible to suppress the variation in the read current in the semiconductor integrated circuit that controls the potential level using the charge sharing, and eventually, it is possible to perform the product-sum operation on the semiconductor integrated circuit in the semiconductor integrated circuit including the SRAM bit cell.

In addition, by increasing the number of global circuit blocks (the number of columns) to be shared at the time of charge sharing, the bit line potential difference per local circuit block increases, and determination can be reliably performed.

Moreover, even in a case where charge sharing is not performed, it is possible to obtain a signal amplitude of a bit line equivalent to that in a case where charge sharing is performed.

Moreover, in the determination circuit, the offset voltage can be reduced, and eventually, the power supply fluctuation during the operation of the input transistor is reduced, the influence of the coupling noise is suppressed, and the accurate determination can be made.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above description, the number of memory cells connected to the local bit line in each local cell array is described as being the same, but it is possible to configure to be different for each local array. According to this configuration, the degree of freedom in design is improved.

What is claimed is:

1. A semiconductor integrated circuit controlling a potential level by charge sharing, wherein
the semiconductor integrated circuit is configured to perform an operation using a potential level controlled by the charge sharing between a plurality of circuit blocks and a global circuit block,
each of the circuit blocks includes a plurality of memory cells, and
the potential level is controlled to be a potential level of a read line for reading data provided according to a state of a memory cell.

2. The semiconductor integrated circuit according to claim 1, wherein a circuit block on which an operation is not to be performed among the plurality of circuit blocks outputs a potential level corresponding to data of a low level or a high level data state.

3. The semiconductor integrated circuit according to claim 1, wherein the semiconductor integrated circuit is configured to
compare a potential level of a result of the operation obtained using a potential level provided by the charge sharing with a reference potential level obtained using a potential level provided by the charge sharing, and
output a result of the comparison as an operation result.

4. The semiconductor integrated circuit according to claim 3, wherein
the circuit block includes a plurality of memory cells having a complementary pair of bit lines, and the global circuit block has a complementary pair of bit lines, and
the semiconductor integrated circuit comprises a switch circuit configured to short a complementary pair of bit lines when the reference potential level is generated.

5. The semiconductor integrated circuit according to claim 3, wherein the reference potential level is generated by using the circuit block on which an operation is not to be performed.

6. The semiconductor integrated circuit according to claim 3, wherein the semiconductor integrated circuit comprises a circuit block configured to generate the reference potential level.

7. The semiconductor integrated circuit according to claim 3, wherein a potential level in the circuit block used for generating the reference potential level is different in accordance with a reference potential level to be generated.

8. The semiconductor integrated circuit according to claim 4, wherein the switch circuit is provided in either the circuit block or the global circuit block.

9. The semiconductor integrated circuit according to claim 1, wherein the semiconductor integrated circuit comprises a latch circuit configured to retain a pre-processing state until data processing is completed when performing the charge sharing between the circuit block and the global circuit block.

10. The semiconductor integrated circuit according to claim 9, wherein the semiconductor integrated circuit comprises a switch circuit configured to connect bit lines between adjacent circuit blocks based on data held by the latch circuit.

11. The semiconductor integrated circuit according to claim 10, wherein the semiconductor integrated circuit is configured to set the number of connections to bit lines of the adjacent circuit blocks based on a state of the latch circuit.

12. The semiconductor integrated circuit according to claim 11, wherein the number of connections of bit lines of the adjacent circuit blocks is set to change only when a reference potential level is generated.

13. The semiconductor integrated circuit according to claim 3, wherein the circuit is configured to switch the connection or disconnection between the circuit block and either bit line of the complementary pair in the global circuit block, based on the state of the circuit block.

14. The semiconductor integrated circuit according to claim 3, wherein the reference potential level is used for determining potential levels of a plurality of operation results.

15. The semiconductor integrated circuit according to claim 3, wherein the semiconductor integrated circuit comprises a circuit configured to perform an operation process on high level data or low level data that are output according to the reference potential level and the potential level of the operation result.

16. The semiconductor integrated circuit according to claim 1, wherein the semiconductor integrated circuit is configured to set an initial potential of a source-drain terminal of a MOS transistor for a differential input, to a power supply potential at a substrate terminal of the MOS transistor.

17. The semiconductor integrated circuit according to claim 1, wherein the semiconductor integrated circuit comprises read circuit groups, each including a plurality of read circuits for reading data provided according to a state of a memory cell, a read circuit group being disposed at a position where the read circuit group to which a lower reference potential level among different reference potential levels obtained using a potential level provided by the charge sharing is supplied operates earlier.

18. The semiconductor integrated circuit according to claim 1, wherein the semiconductor integrated circuit comprises read circuit groups, each including a plurality of read circuits for reading data provided according to a state of the memory cell, a lower reference potential level being supplied to a read circuit group having a higher wiring load with the memory cell.

19. The semiconductor integrated circuit according to claim 17, wherein the read circuit group to which a lower reference potential level is supplied is disposed at a position where a wiring load between the read circuit group and a drive buffer circuit that drives a data read circuit is smaller.

20. The semiconductor integrated circuit according to claim 18, wherein the read circuit group to which a lower reference potential level is supplied is disposed at a position where a wiring load between the read circuit group and a drive buffer circuit for driving a data read circuit is smaller.
